(19) United States
(12) Patent Application Publication
(10) Pub. No.: US 2024/0274698 A1
(43) Pub. Date: Aug. 15, 2024

(54) SEMICONDUCTOR DEVICE AND MANUFACTURING METHOD OF SEMICONDUCTOR DEVICE

(71) Applicant: FUJI ELECTRIC CO., LTD., Kanagawa (JP)

(72) Inventors: Misaki UCHIDA, Matsumoto-city (JP); Takashi YOSHIMURA, Matsumoto-city (JP); Shuntaro YAGUCHI, Matsumoto-city (JP)

(21) Appl. No.: 18/583,764

(22) Filed: Feb. 21, 2024

Related U.S. Application Data
(63) Continuation of application No. PCT/JP2023/010080, filed on Mar. 15, 2023.

(30) Foreign Application Priority Data
Mar. 16, 2022 (JP) 2022-040938

(51) Int. Cl. H01L 29/739; H01L 27/07; H01L 29/10; H01L 29/32; H01L 29/36; H01L 29/861

(52) U.S. Cl. CPC H01L 29/7397; H01L 27/0727; H01L 29/1095; H01L 29/32; H01L 29/36; H01L 29/861

(57) ABSTRACT

Provided is a semiconductor device comprising: a drift region in a semiconductor substrate having a front surface and a back surface; and a buffer region in the back surface side of the semiconductor substrate relative to the drift region in a depth direction of the semiconductor substrate, wherein the buffer region has a group of concentration peaks including one or more concentration peaks of a doping concentration, the group of concentration peaks includes a first concentration peak provided closest, among the one or more concentration peaks, to the back surface of the semiconductor substrate, the semiconductor substrate includes a first hydrogen peak which is a peak of an atomic density of hydrogen, provided in a same depth position as that of the first concentration peak or in the back surface side of the semiconductor substrate relative to a depth position of the first concentration peak.

The contents of the following patent application(s) are incorporated herein by reference:
NO. 2022-040938 filed in JP on Mar. 16, 2022
NO. PCT/JP2023/010080 filed in WO on Mar. 15, 2023

### BACKGROUND

### 1. Technical Field

The present invention relates to a semiconductor device and a manufacturing method of the semiconductor device.

### 2. Related Art

Patent document 1 describes a semiconductor device having “a proton layer doped with proton” in “an FS layer”.

### PRIOR ART DOCUMENT

### Patent Document

Patent Document 1: Japanese Patent No. 5817686
Patent document 2: PCT International Publication No. WO2018/179798

### BRIEF DESCRIPTION OF THE DRAWINGS

FIG. 1A illustrates an example of a top view of a semiconductor device 100.

FIG. 1B illustrates an example of a cross section a-a′ in FIG. 1A.

FIG. 2A is an example of a top view showing a modification example of the semiconductor device 100.

FIG. 2B is an enlarged drawing of region A in FIG. 2A.

FIG. 2C shows a b-b′ a cross section of a modification example of the semiconductor device 100.

FIG. 3A illustrates an example of a concentration distribution of a doping concentration in a buffer region 20.

FIG. 3B illustrates a modification example of the concentration distribution of the doping concentration in the buffer region 20.

FIG. 3C illustrates a modification example of the concentration distribution of the doping concentration in the buffer region 20.

FIG. 3D illustrates a modification example of the concentration distribution of the doping concentration in the buffer region 20.

FIG. 3E illustrates a modification example of the concentration distribution of the doping concentration in the buffer region 20.

FIG. 4A illustrates an example of a doping concentration distribution in a semiconductor substrate 10.

FIG. 4B illustrates an example of a doping concentration distribution in a semiconductor substrate 10 as a modification example.

FIG. 5 is a drawing to describe a difference in a degree of activation according to an annealing temperature.

FIG. 6 is an example of distribution of doping concentration in a buffer region 520 as a comparative example.

FIG. 7A is a flowchart showing an example of a manufacturing process of the semiconductor device 100.

FIG. 7B is a flowchart showing a modification example of the manufacturing process of the semiconductor device 100.

FIG. 7C is a flowchart showing a modification example of the manufacturing process of the semiconductor device 100.

### DESCRIPTION OF EXEMPLARY EMBODIMENTS

Hereinafter, the present invention will be described through embodiments of the present invention, but the following embodiments do not limit the invention according to claims. In addition, not all of the combinations of features described in the embodiments are essential to the solving means of the invention.

As used herein, one side in a direction parallel to a depth direction of a semiconductor substrate is referred to as “upper” and the other side is referred to as “lower”. One surface of two principal surfaces of a substrate, a layer or other member is referred to as an upper surface, and the other surface is referred to as a lower surface. “Upper” and “lower” directions are not limited to a direction of gravity, or a direction in which a semiconductor device is mounted.

In the present specification, technical matters may be described using orthogonal coordinate axes of an X axis, a Y axis, and a Z axis. The orthogonal coordinate axes merely specify relative positions of components, and do not limit a specific direction. For example, the Z axis is not limited to indicate the height direction with respect to the ground. Note that a +Z axis direction and a −Z axis direction are directions opposite to each other. When the Z axis direction is described without describing the signs, it means that the direction is parallel to the +Z axis and the −Z axis.

In the present specification, orthogonal axes parallel to the upper surface and the lower surface of the semiconductor substrate are referred to as the X axis and the Y axis. Further, an axis perpendicular to the upper surface and the lower surface of the semiconductor substrate is referred to as the Z axis. In the present specification, the direction of the Z axis may be referred to as the depth direction. Further, in the present specification, a direction parallel to the upper surface and the lower surface of the semiconductor substrate may be referred to as a horizontal direction, including an X axis direction and a Y axis direction.

In the present specification, a case where a term such as “same” or “equal” is mentioned may include a case where an error due to a variation in manufacturing or the like is included. The error is, for example, within 10%.

In the present specification, a conductivity type of doping region where doping has been carried out with an impurity is described as a P type or an N type. In the present specification, the impurity may particularly mean either a donor of the N type or an acceptor of the P type, and may be described as a dopant. In the present specification, doping means introducing the donor or the acceptor into the semiconductor substrate and turning it into a semiconductor presenting a conductivity type of the N type, or a semiconductor presenting conductivity type of the P type.

In the present specification, a doping concentration means a concentration of the donor or a concentration of the acceptor in a thermal equilibrium state. In the present specification, a net doping concentration means a net concentration obtained by adding the donor concentration set as a positive ion concentration to the acceptor concentration set as a negative ion concentration, taking into account of polarities of charges. As an example, when the donor concentration is ND and the acceptor concentration is NA, the net doping concentration at any position is given as ND-NA. In the present specification, the net doping concentration may be simply referred to as the doping concentration.

The donor has a function of supplying electrons to a semiconductor. The acceptor has a function of receiving electrons from the semiconductor. The donor and the acceptor are not limited to the impurities themselves. For example, a VOH defect which is a combination of a vacancy (V), oxygen (O), and hydrogen (H) existing in the semiconductor functions as the donor that supplies electrons. In the present specification, the VOH defect may be referred to as a hydrogen donor. Moreover in the present specification, ion-implanted hydrogen for forming a hydrogen donor may be referred to as a dopant.

In the present specification, a description of a P+ type or an N+ type means a higher doping concentration than that of the P type or the N type, and a description of a P− type or an N− type means a lower doping concentration than that of the P type or the N type. Further, in the specification, a description of a P++ type or an N++ type means a higher doping concentration than that of the P+ type or the N+ type.

A chemical concentration in the present specification indicates an atomic density of an impurity measured regardless of an electrical activation state. The chemical concentration can be measured by, for example, secondary ion mass spectrometry (SIMS). The net doping concentration described above can be measured by capacitance-voltage profiling (CV profiling). Further, a carrier concentration measured by spreading resistance profiling (SRP method) may be set as the net doping concentration. The carrier concentration measured by the CV profiling or the SRP method may be a value in a thermal equilibrium state. Further, in a region of the N type, the donor concentration is sufficiently higher than the acceptor concentration, and thus the carrier concentration of the region may be set as the donor concentration. Similarly, in a region of the P type, the carrier concentration of the region may be set as the acceptor concentration. In the present specification, the doping concentration of the N type region may be referred to as the donor concentration, and the doping concentration of the P type region may be referred to as the acceptor concentration.

Further, when a concentration distribution of the donor, acceptor, or net doping has a peak in a region, a value of the peak may be set as the concentration of the donor, acceptor, or net doping in the region. In a case where the concentration of the donor, acceptor or net doping is substantially uniform in a region, or the like, an average value of the concentration of the donor, acceptor or net doping in the region may be set as the concentration of the donor, acceptor or net doping.

The carrier concentration measured by the SRP method may be lower than the concentration of the donor or the acceptor. In a range where a current flows when a spreading resistance is measured, carrier mobility of the semiconductor substrate may be lower than a value in a crystalline state. The reduction in carrier mobility occurs when carriers are scattered due to disorder (disorder) of a crystal structure due to a lattice defect or the like.

The concentration of the donor or the acceptor calculated from the carrier concentration measured by the CV profiling or the SRP method may be lower than a chemical concentration of an element indicating the donor or the acceptor. As an example, in a silicon semiconductor, a donor concentration of phosphorous or arsenic serving as a donor, or an acceptor concentration of boron (boron) serving as an acceptor is approximately 99% of chemical concentrations of these. On the other hand, in the silicon semiconductor, a donor concentration of hydrogen serving as a donor is approximately 0.1% to 10% of a chemical concentration of hydrogen. In the present specification, an SI unit system is adopted. In the present specification, a unit of a distance or length may be represented by cm (centimeter). In this case, various calculations may be converted into m (meter) to be calculated. As for numeric representation of power of 10, for example, the representation 1E+16 indicates 1×10¹⁶, and the representation 1E−16 indicates 1×10⁻¹⁶.

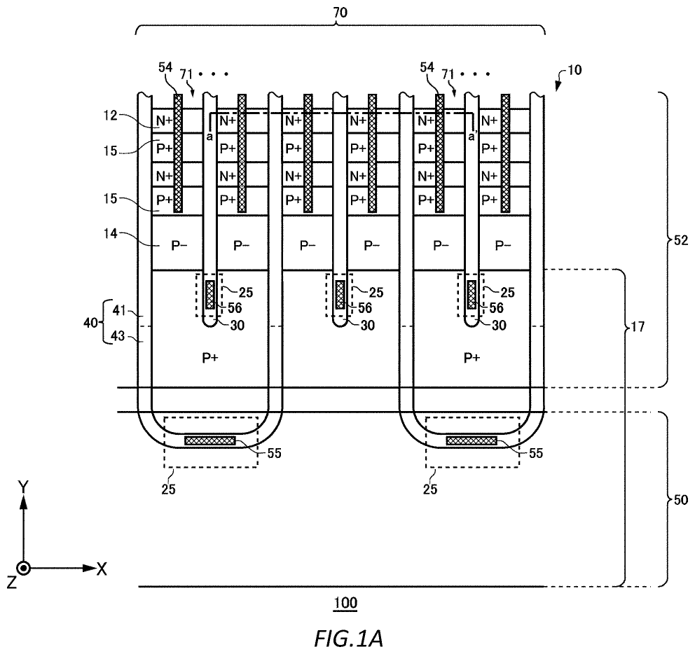

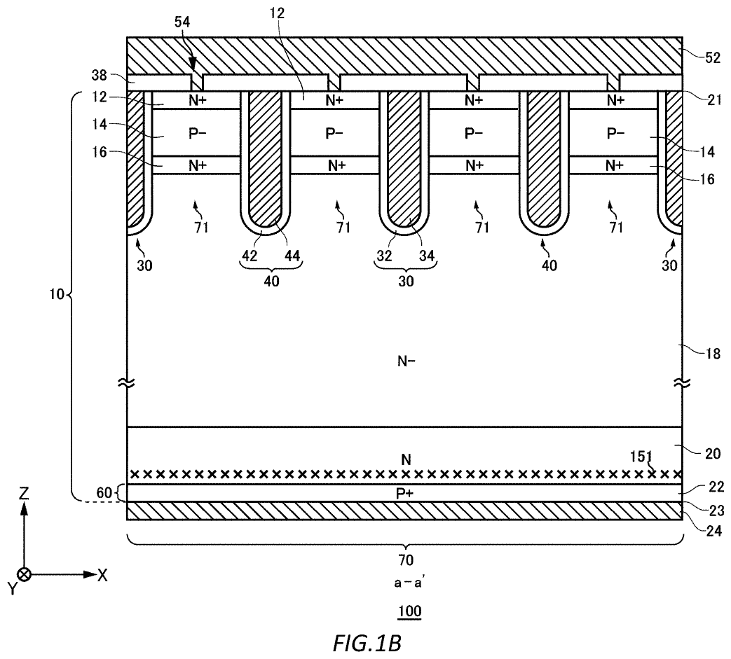

FIG. 1A illustrates an example of the top view of a semiconductor device 100. The semiconductor device 100 in the present example is a semiconductor chip that includes a transistor portion 70.

The transistor portion 70 is a region obtained by projecting a collector region 22 provided in a back surface side of a semiconductor substrate 10 onto an upper surface of the semiconductor substrate 10. The collector region 22 will be described below. The transistor portion 70 includes a transistor such as an IGBT. In the present example, the transistor portion 70 is an IGBT. It is to be noted that the transistor portion 70 may be other transistors such as a MOSFET.

The present figure shows a surrounding region of a chip end portion on an edge side of the semiconductor device 100, and other regions are omitted. For example, an edge termination structure portion may be provided in a region in a negative side of the Y axis direction in the semiconductor device 100 in the present example. The edge termination structure portion is to relax an electric field strength in the upper surface side of the semiconductor substrate 10. The edge termination structure portion includes, for example, a guard ring, a field plate, or a RESURF structure, or combinations thereof. Note that although the present example describes the edge in the negative side in the Y axis direction for convenience, the same applies to other edges of the semiconductor device 100.

The semiconductor substrate 10 is a substrate that is formed of a semiconductor material. The semiconductor substrate 10 may be a silicon substrate, a silicon carbide substrate, a nitride semiconductor substrate such as gallium nitride, or the like. The semiconductor substrate 10 of the present example is a silicon substrate. It is to be noted that when simply referred to as a top view in the present specification, it means that the upper surface side of the semiconductor substrate 10 is viewed from above. As will be described later, the semiconductor substrate 10 includes a front surface 21 and a back surface 23.

The semiconductor device 100 in the present example includes, at a front surface 21 of the semiconductor substrate 10, a gate trench portion 40, a dummy trench portion 30, an emitter region 12, a base region 14, a contact region 15, and a well region 17. In addition, the semiconductor device 100 in the present example includes an emitter electrode 52 and a gate metal layer 50 which are provided above the front surface 21 of the semiconductor substrate 10.

The emitter electrode 52 is provided above the gate trench portion 40, the dummy trench portion 30, the emitter region 12, the base region 14, the contact region 15, and the well region 17. In addition, the gate metal layer 50 is provided above the gate trench portion 40 and the well region 17.

The emitter electrode 52 and the gate metal layer 50 are formed of a material including metal. At least a partial region of the emitter electrode 52 may be formed of metal such as aluminum (Al) or a metal alloy such as an aluminum-silicon alloy (AlSi) and an aluminum-silicon-copper alloy (AlSiCu). At least a partial region of the gate metal layer 50 may be formed of metal such as aluminum (Al) or a metal alloy such as an aluminum-silicon alloy (AlSi) and an aluminum-silicon-copper alloy (AlSiCu). The emitter electrode 52 and the gate metal layer 50 may include a barrier metal formed of titanium, titanium compound, or the like, which underlies a region formed of aluminum or the like. The emitter electrode 52 and the gate metal layer 50 are provided separately from each other.

The emitter electrode 52 and the gate metal layer 50 are provided above the semiconductor substrate 10 to sandwich an interlayer dielectric film 38. The interlayer dielectric film 38 is omitted in FIG. 1A. A contact hole 54, a contact hole 55, and a contact hole 56 are provided through the interlayer dielectric film 38.

The contact holes 55 connect the gate metal layer 50 and the gate conductive portions inside the transistor portions 70. A plug metal layer formed of tungsten or the like may be formed inside the contact hole 55.

The contact hole 56 connects the emitter electrode 52 with a dummy conductive portion in a dummy trench portion 30. A plug metal layer formed of tungsten or the like may be formed inside the contact hole 56.

A connection portion 25 is connected to an electrode on the side of the front surface, such as an emitter electrode 52 or the gate metal layer 50. In an example, the connection portion 25 is provided between the gate metal layer 50 and the gate conductive portion. The connection portion 25 is also provided between the emitter electrode 52 and the dummy conductive portion. The connection portion 25 is formed of a conductive material such as polysilicon doped with impurities. The connection portion 25 in the present example is polysilicon doped with an N type impurity (N+). The connection portion 25 is provided above the front surface 21 of the semiconductor substrate 10 via a dielectric film such as an oxide film, or the like.

The gate trench portions 40 are an example of a plurality of trench portions extending in a predetermined extending direction on the front surface 21 side of the semiconductor substrate 10. The gate trench portions 40 are arrayed at predetermined intervals along a predetermined array direction (the X axis direction in the present example). The gate trench portion 40 in the present example may include: two extending portions 41 which extend along an extending direction (the Y axis direction in the present example) parallel to the front surface 21 of the semiconductor substrate 10 and perpendicular to the array direction; and a connecting portion 43 which connects two extending portions 41.

Preferably, at least a part of the connecting portion 43 is formed in a curved shape. By connecting end portions of the two extending portions 41 of the gate trench portion 40, an electric field strength at the end portions of the extending portions 41 can be reduced. At the connecting portion 43 of the gate trench portion 40, the gate metal layer 50 may be connected to the gate conductive portion.

The dummy trench portions 30 are an example of the plurality of trench portions extending in the predetermined extending direction on the front surface 21 side of the semiconductor substrate 10. The dummy trench portion 30 is a trench portion that is electrically connected to the emitter electrode 52. Similar to the gate trench portions 40, the dummy trench portions 30 are arrayed at predetermined intervals along a predetermined array direction (the X axis direction in the present example). Although the dummy trench portion 30 of the present example has an I shape on the front surface 21 of the semiconductor substrate 10, it may have a U shape on the front surface 21 of the semiconductor substrate 10 similar to the gate trench portion 40. That is, the dummy trench portion 30 may include two extending portions extending along the extending direction and a connecting portion which connects the two extending portions.

The transistor portion 70 of the present example has a structure in which two gate trench portions 40 and two dummy trench portions 30 are arrayed repetitively. That is, the transistor portion 70 of the present example includes the gate trench portions 40 and the dummy trench portions 30 at a ratio of 1:1. For example, the transistor portion 70 includes one dummy trench portion 30 between two extending portions 41.

It is noted however that the ratio of the gate trench portions 40 and the dummy trench portions 30 is not limited to the present example. The ratio of the gate trench portions 40 may be larger than the ratio of the dummy trench portions 30, or the ratio of the dummy trench portions 30 may be larger than the ratio of the gate trench portions 40. The ratio between the gate trench portions 40 and the dummy trench portions 30 may be 2:3 or may be 2:4. Alternatively, with all trench portions being the gate trench portions 40, the transistor portion 70 does not need to include the dummy trench portion 30.

The well region 17 is a region of a second conductivity type which is provided in a front surface 21 side of the semiconductor substrate 10 relative to a drift region 18 which will be described below. The well region 17 is an example of the well region provided in the edge side of the semiconductor device 100. The well region 17 is of the P+ type as an example. The well region 17 is formed within a predetermined range from an end portion of the active region in a side in which the gate metal layer 50 is provided. A diffusion depth of the well region 17 may be deeper than depths of the gate trench portion 40 and the dummy trench portion 30. Partial regions of the gate trench portion 40 and the dummy trench portion 30 in the gate metal layer 50 side are formed in the well region 17. The bottoms at the end of the extending direction of the gate trench portion 40 and the dummy trench portion 30 may be covered by the well region 17.

The contact hole 54 is formed above each region of the emitter region 12 and the contact region 15 in the transistor portion 70. The contact hole 54 is not provided above the well regions 17 provided at both ends in the Y axis direction. In this manner, one or more contact holes 54 are formed in the interlayer dielectric film. The one or more contact holes 54 may be provided to extend in the extending direction.

A mesa portion 71 is a mesa portion provided adjacent to the trench portion in a plane parallel to the front surface 21 of the semiconductor substrate 10. The mesa portion may be a portion of the semiconductor substrate 10 sandwiched between two trench portions adjacent to each other, and may be a portion ranging from the front surface 21 of the semiconductor substrate 10 to the depth of the lowermost bottom portion of each trench portion. The extending portions of each trench portion may be set to be one trench portion. That is, the region sandwiched between two extending portions may be set to be a mesa portion.

The mesa portion 71 is provided adjacent to at least one of the dummy trench portion 30 or the gate trench portion 40 in the transistor portion 70. The mesa portion 71 includes the well region 17, the emitter region 12, the base region 14, and the contact region 15 at the front surface 21 of the semiconductor substrate 10. The mesa portion 71 includes the emitter regions 12 and the contact regions 15 alternately provided in the extending direction.

The base region 14 is a region of the second conductivity type which is provided in the front surface 21 side of the semiconductor substrate 10. The base region 14 is of the P− type as an example. The base regions 14 may be provided at both end portions of the mesa portion 71 in the Y axis direction in the front surface 21 of the semiconductor substrate 10. Note that FIG. 1A illustrates only one end portion in the Y axis direction of the base region 14.

The emitter region 12 is a region of the first conductivity type having a higher doping concentration than that of the drift region 18. The emitter region 12 in the present example is of the N+ type as an example. One example of a dopant of the emitter region 12 is arsenic (As). The emitter region 12 is provided in contact with the gate trench portion 40 at the front surface 21 in the mesa portion 71. The emitter region 12 may be provided to extend in the X axis direction from one of two trench portions sandwiching the mesa portion 71 to the other one of the two trench portions. The emitter region 12 is also provided below the contact hole 54.

In addition, the emitter region 12 may or may not be in contact with the dummy trench portion 30. The emitter region 12 of the present example is in contact with the dummy trench portion 30.

The contact region 15 is a region of a second conductivity type, which is provided above the base region 14 and has a higher doping concentration than the base region 14. The contact region 15 in the present example is of the P+ type as an example. The contact region 15 in the present example is provided in the front surface 21 of the mesa portion 71. The contact region 15 may be provided in the X axis direction from one of two trench portions sandwiching the mesa portion 71 to the other of the two trench portions. The contact region 15 may or may not be in contact with the gate trench portion 40 or the dummy trench portion 30. The contact region 15 in the present example is in contact with the dummy trench portion 30 and the gate trench portion 40. The contact region 15 is also provided below the contact hole 54.

FIG. 1B illustrates an example of a cross section a-a′ in FIG. 1A. The cross section a-a′ is an XZ plane which extends through the emitter region 12 in the transistor portion 70. In the cross section a-a′, the semiconductor device 100 in the present example has the semiconductor substrate 10, the interlayer dielectric film 38, the emitter electrode 52, and a collector electrode 24. The emitter electrode 52 is formed above the semiconductor substrate 10 and the interlayer dielectric film 38.

The drift region 18 is a region of the first conductivity type which is provided in the semiconductor substrate 10. The drift region 18 in the present example is of the N− type as an example. The drift region 18 may be a region that has remained without other doping regions being formed in the semiconductor substrate 10. That is, the doping concentration of the drift region 18 may be a doping concentration of the semiconductor substrate 10.

A buffer region 20 is a region of the first conductivity type which is provided in a back surface 23 side of the semiconductor substrate 10 relative to the drift region 18. The buffer region 20 in the present example is of the N type as an example. The doping concentration of the buffer region 20 is higher than the doping concentration of the drift region 18. The buffer region 20 may function as a field stop layer which prevents a depletion layer extending from a lower surface side of the base region 14 from reaching the collector region 22 of the second conductivity type. It is to be noted that the buffer region 20 may be omitted.

A back-surface-side region 60 is provided in a back surface 23 side of the semiconductor substrate 10 relative to the drift region 18. The back-surface-side region 60 has a concentration peak of a doping concentration of the second conductivity type or of the first conductivity type. The back-surface-side region 60 of the present example has a concentration peak of a doping concentration of the second conductivity type. The transistor portion 70 of the present example includes a collector region 22 as the back-surface-side region 60. The upper end of the back-surface-side region 60 of the present example is in contact with the lower end of the buffer region 20. Note that in the present specification, the upper end may refer to the end of front surface 21 side in the depth direction of the semiconductor substrate 10, and the lower end may refer to the end of the back surface 23 side in the depth direction of the semiconductor substrate 10. An “upper end” and “lower end” is not limited to a direction of gravity, or a direction in which the semiconductor device 100 is mounted.

The collector region 22 is provided below the buffer region 20 in the transistor portion 70. The collector region 22 has the second conductivity type. As an example, the collector region 22 of the present example is of the P+ type.

The collector electrode 24 is formed at the back surface 23 of the semiconductor substrate 10. The collector electrode 24 is formed of a conductive material such as metal. The material of the collector electrode 24 may be the same as or different from the material of the emitter electrode 52.

The base region 14 is a region of the second conductivity type which is provided above the drift region 18. The base region 14 is provided in contact with the gate trench portion 40. The base region 14 may be provided in contact with the dummy trench portion 30.

The emitter region 12 is provided above the base region 14. The emitter region 12 is provided between the base region 14 and the front surface 21. The emitter region 12 is provided in contact with the gate trench portion 40. The emitter region 12 may or may not be in contact with the dummy trench portion 30.

The accumulation region 16 is a region of the first conductivity type which is provided in the front surface 21 side of the semiconductor substrate 10 relative to the drift region 18. The accumulation region 16 in the present example is of the N+ type as an example. It is noted however that the accumulation region 16 may not be provided.

The accumulation region 16 is provided in contact with the gate trench portion 40. The accumulation region 16 may or may not be in contact with the dummy trench portion 30. The doping concentration of the accumulation region 16 is higher than the doping concentration of the drift region 18. An ion implantation dose amount of the accumulation region 16 may be 1.0E+12 cm⁻² or more and 1.0E+13 cm⁻² or less. Alternatively, the ion implantation dose amount of the accumulation region 16 may be 3.0E+12 cm⁻² or more and 6.0E+12 cm⁻² or less. Providing the accumulation region 16 can enhance the carrier injection enhancement effect (IE effect) to reduce an ON voltage of the transistor portion 70.

One or more gate trench portions 40 and one or more dummy trench portions 30 are provided at the front surface 21. Each trench portion is provided from the front surface 21 to the drift region 18. In a region provided with at least any of the emitter region 12, the base region 14, the contact region 15, or the accumulation region 16, each trench portion also passes through these regions to reach the drift region 18. The configuration of the trench portion penetrating the doping region is not limited to the one manufactured in the order of forming the doping region and then forming the trench portion. The configuration of the trench portion passing through the doping region also includes a configuration of the doping region being formed between the trench portions after forming the trench portions.

The gate trench portion 40 has a gate trench, a gate dielectric film 42, and a gate conductive portion 44 which are formed in the front surface 21. The gate dielectric film 42 is formed to cover an inner wall of the gate trench. The gate dielectric film 42 may be formed by oxidizing or nitriding a semiconductor on the inner wall of the gate trench. The gate dielectric film 42 is formed in the interior of the gate trench, and the gate conductive portion 44 is formed inside the gate dielectric film 42. The gate dielectric film 42 insulates the gate conductive portion 44 from the semiconductor substrate 10. The gate conductive portion 44 is formed of a conductive material such as polysilicon. The gate trench portion 40 is covered by the interlayer dielectric film 38 on the front surface 21.

The gate conductive portion 44 includes a region opposing the adjacent base region 14 in the mesa portion 71 side by sandwiching the gate dielectric film 42 in a depth direction of the semiconductor substrate 10. When a predetermined voltage is applied to the gate conductive portion 44, a channel is formed to a surface layer being at a boundary within the base region 14 and in contact with the gate trench, due to an electron inversion layer.

The dummy trench portion 30 may have the same structure as the gate trench portion 40. The dummy trench portion 30 includes a dummy trench, a dummy dielectric film 32, and a dummy conductive portion 34 formed in the front surface 21 side. The dummy dielectric film 32 is formed covering the inner walls of the dummy trench. The dummy conductive portion 34 is formed in the interior of the dummy trench and also formed inside the dummy dielectric film 32. The dummy dielectric film 32 insulates the dummy conductive portion 34 from the semiconductor substrate 10. The dummy trench portion 30 is covered by the interlayer dielectric film 38 on the front surface 21.

The interlayer dielectric film 38 is provided above the semiconductor substrate 10. The interlayer dielectric film 38 of the present example is provided in contact with the front surface 21. The emitter electrode 52 is provided above the interlayer dielectric film 38. In the interlayer dielectric film 38, one or more contact holes 54 are provided for electrically connecting the emitter electrode 52 to the semiconductor substrate 10. Similarly, the contact hole 55 and the contact hole 56 may be provided to penetrate through the interlayer dielectric film 38. The interlayer dielectric film 38 may be a BPSG (Boro-phospho Silicate Glass) film, may be a BSG (borosilicate glass) film, may be a PSG (Phosphosilicate glass) film, may be an HTO film, or may be a film obtained by stacking these materials. A thickness of the interlayer dielectric film 38 is, for example, 1.0 μm, but is not limited to this.

A first lifetime control region 151 may be provided on the transistor portion 70. However, the first lifetime control region 151 may be omitted. The first lifetime control region 151 is a region where a lifetime killer has intentionally been formed by implanting an impurity inside the semiconductor substrate 10, or the like. As an example, the first lifetime control region 151 is formed by implanting helium into the semiconductor substrate 10. By providing the first lifetime control region 151, a turn-off time can be reduced, and by suppressing a tail current, losses during switching can be reduced.

The lifetime killer is a recombination center of carriers. The lifetime killer may be a lattice defect. For example, the lifetime killer may be a vacancy, a divacancy, a defect complex of these with elements configuring the semiconductor substrate 10, or dislocation. Furthermore, the lifetime killer may be a noble gas element such as helium and neon, a metal element such as platinum, or the like. An electron beam may be used for forming the lattice defect.

A lifetime killer concentration is a concentration at the recombination center of carriers. The lifetime killer concentration may be a concentration of the lattice defect. For example, the lifetime killer concentration may be a vacancy concentration of a vacancy, a divacancy, or the like, may be a defect complex concentration of these vacancies with elements configuring the semiconductor substrate 10, or may be a dislocation concentration. Alternatively, the lifetime killer concentration may be a chemical concentration of the noble gas element such as helium and neon, or may be a chemical concentration of the metal element such as platinum.

The first lifetime control region 151 is provided in the back surface 23 side relative to the center of the semiconductor substrate 10 in the depth direction of the semiconductor substrate 10. The first lifetime control region 151 in the present example is provided in the buffer region 20. The first lifetime control region 151 in the present example is provided at an entire surface of the semiconductor substrate 10 in the XY plane, and can be formed without using a mask. The first lifetime control region 151 may be provided in a part of the semiconductor substrate 10 in the XY plane. The dose amount of the impurity to form the first lifetime control region 151 may be 0.5E+10 cm⁻² or more and 1.0E+13 cm⁻² or less, or may be 5.0E+10 cm⁻² or more and I 5.0E+11 cm⁻² or less.

The first lifetime control region 151 may be formed through the implantation from the back surface 23 side. With this configuration, an impact in the front surface 21 side of the semiconductor device 100 can be avoided. For example, the first lifetime control region 151 is formed by irradiating helium from the back surface 23 side. Herein, which of the front surface 21 side and the back surface 23 side the implantation is performed from for forming the first lifetime control region 151 can be determined by acquiring a state of the front surface 21 side by an SRP method or a measurement of a leakage current.

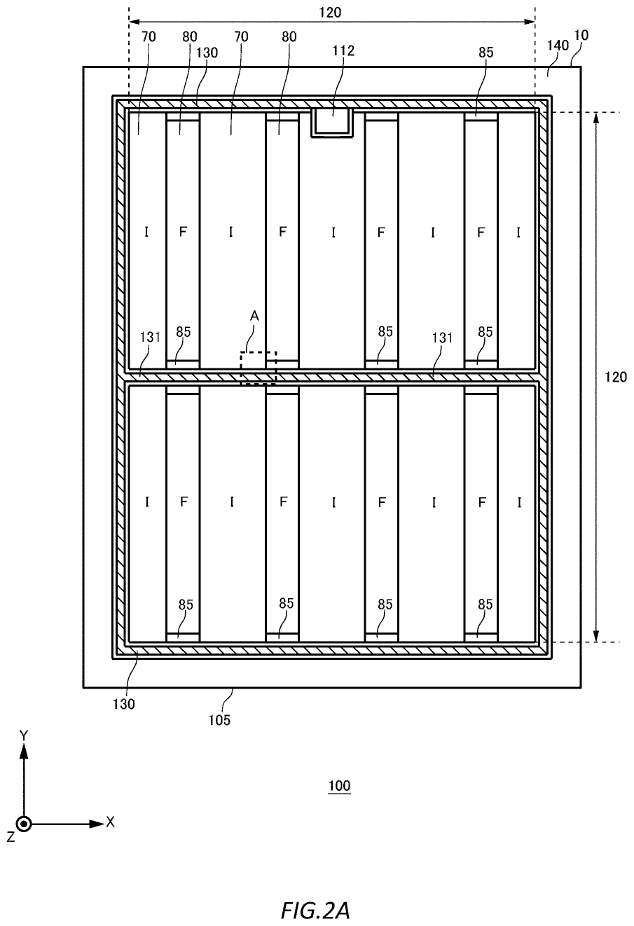

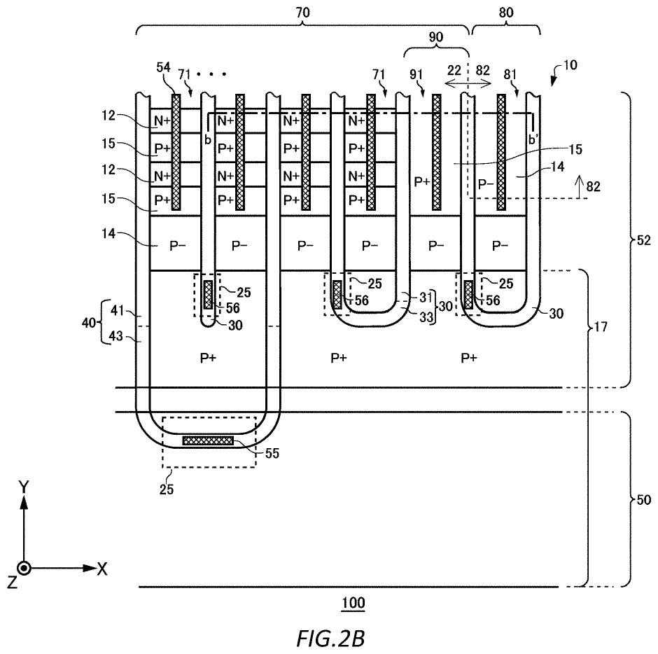

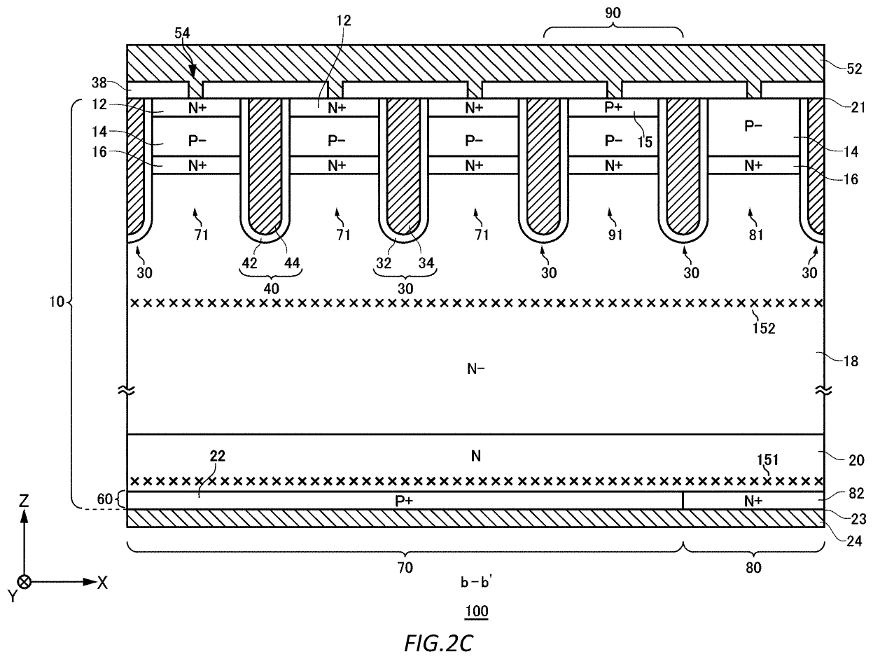

FIG. 2A is an example of a top view showing a modification example of the semiconductor device 100. FIG. 2A shows a position at which each member is projected on an upper surface of a semiconductor substrate 10. FIG. 2A shows merely some members of the semiconductor device 100, and omits some members.

The semiconductor substrate 10 has end sides 105 in a top view. The semiconductor substrate 10 of present example has two sets of end sides 105 opposite to each other in the top view. In FIG. 2A, the X axis and the Y axis are parallel to any of the end sides 105.

The semiconductor substrate 10 is provided with an active section 120. The active section 120 is a region where a principal current flows in the depth direction between the front surface 21 and the back surface 23 of the semiconductor substrate 10 when the semiconductor device 100 operates. An emitter electrode 52 is provided above the active portion 120, but is omitted in FIG. 2A.

The active section 120 is provided with at least one of a transistor portion 70 including a transistor element such as an IGBT, or a diode portion 80 including a diode element such as a free wheeling diode (FWD). The semiconductor device 100 of present example is an RC-IGBT including the transistor portion 70 and the diode portion 80. In the example of FIG. 2A, the transistor portion 70 and the diode portion 80 are alternately arranged along a predetermined array direction (the X axis direction in present example) on the front surface 21 of the semiconductor substrate 10. The active portion 120 in another example may be provided with only one of the transistor portion 70 and the diode portion 80.

In this figure, a region where the transistor portion 70 is arranged is denoted by a symbol “I”, and a region where the diode portion 80 is arranged is denoted by a symbol “F”. Each of the transistor portions 70 and the diode portions 80 may have a longitudinal length in the extending direction. In other words, the length of each of the transistor portions 70 in the Y axis direction is larger than the width in the X axis direction. Similarly, the length of each of the diode portions 80 in the Y axis direction is larger than the width in the X axis direction.

The extending direction of the transistor portion 70 and the diode portion 80, and the longitudinal direction of each trench portion described later may be the same.

The diode portion 80 includes a cathode region of N+ type in a region in contact with the back surface 23 of the semiconductor substrate 10. In the present specification, a region where the cathode region is provided is referred to as the diode portion 80. In other words, the diode portion 80 is a region that overlaps with the cathode region in the top view. The back surface 23 of the semiconductor substrate 10 may be provided with a collector region 22 of the P+ type in a region other than the cathode region. In the specification, the diode portion 80 may also include an extension region 85 where the diode portion 80 extends to a gate runner described below in the Y axis direction. The collector region 22 is provided on the back surface 23 of the extension region 85.

The semiconductor device 100 may have one or more pads above the semiconductor substrate 10. The semiconductor device 100 of present example has a gate pad 112. The semiconductor device 100 may have a pad such as an anode pad, a cathode pad, and a current detection pad. Each pad is arranged in a region close to the end side 105. The region close to the end side 105 refers to a region between the end side 105 and the emitter electrode 52 in the top view. When the semiconductor device 100 is mounted, each pad may be connected to an external circuit via a wiring such as a wire.

A gate potential is applied to the gate pad 112. The gate pad 112 is electrically connected to the gate conductive portion 44 of the gate trench portion 40 of the active portion 120. The semiconductor device 100 includes a gate runner that connects the gate pad 112 and the gate trench portion 40. In this figure, the gate runner is hatched with diagonal lines.

The gate runner of present example has an outer circumferential gate runner 130 and an active-side gate runner 131. The outer circumferential gate runner 130 and the active-side gate runner 131 are an example of the gate metal layer 50. The outer circumferential gate runner 130 is arranged between the active portion 120 and the end side 105 of the semiconductor substrate 10 in the top view. The outer circumferential gate runner 130 of present example surrounds the active section 120 in the top plan view. A region surrounded by the outer circumferential gate runner 130 in the top plan view may be the active section 120. Further, the outer circumferential gate runner 130 is connected to the gate pad 112. The outer circumferential gate runner 130 is arranged above the semiconductor substrate 10. The outer circumferential gate runner 130 may be a metal wiring including aluminum or the like.

The active-side gate runner 131 is provided in the active section 120. Providing the active-side gate runner 131 in the active section 120 can reduce a variation in wiring length from the gate pad 112 for each region of the semiconductor substrate 10.

The active-side gate runner 131 is connected to the gate trench portion of the active section 120. The active-side gate runner 131 is arranged above the semiconductor substrate 10. The active-side gate runner 131 may be a wiring formed of a semiconductor such as polysilicon doped with an impurity.

The active-side gate runner 131 may be connected to the outer circumferential gate runner 130. The active-side gate runner 131 of present example is provided extending in the X axis direction so as to cross the active section 120 from one outer circumferential gate runner 130 to the other outer circumferential gate runner 130 substantially at the center of the Y axis direction. In a case where the active portion 120 is divided by the active-side gate runner 131, the transistor portion 70 and the diode portion 80 may be alternately arranged in the X axis direction in each divided region.

Further, the semiconductor device 100 may include a temperature sensing portion (not shown) that is a PN junction diode formed of polysilicon or the like, or a current detection portion (not shown) that simulates an operation of the transistor portion provided in the active portion 120.

An edge termination structure portion 140 is provided on the front surface 21 of the semiconductor substrate 10. The edge termination structure portion 140 is provided between the active portion 120 and the end side 105 in the top view. The edge termination structure portion 140 of present example is arranged between the outer circumferential gate runner 130 and the end side 105. The edge termination structure portion 140 is configured to reduce electric field strength on the front surface side 21 of the semiconductor substrate 10. The edge termination structure portion 140 may include at least one of a guard ring, a field plate, and a RESURF which are annularly provided to enclose the active portion 120.

FIG. 2B is an enlarged view of a region A in FIG. 2A. The region A is a region including the transistor portion 70 and the diode portion 80. The diode portion 80 is a region where the cathode region 82 provided on the back surface 23 side of the semiconductor substrate 10 is projected on the upper surface of the semiconductor substrate 10. The semiconductor device 100 of present example includes the gate trench portion 40, the dummy trench portion 30, the emitter region 12, the base region 14, the contact region 15, and the well region 17, which are provided inside the semiconductor substrate 10 on the upper surface side. The gate trench portion 40 and the dummy trench portion 30 each are an example of the trench portion.

Similar to the gate trench portion 40, the dummy trench portion 30 of the present example may have a U shape on the front surface 21 of the semiconductor substrate 10. That is, the dummy trench portion 30 may include two extending portions 31 which extend along the extending direction and a connecting portion 33 which connects two extending portions 31.

The semiconductor device 100 of the present example includes the emitter electrode 52 and the gate metal layer 50 provided above the front surface 21 of the semiconductor substrate 10. The emitter electrode 52 and the gate metal layer 50 are provided separated from each other. The transistor portion 70 in the present example includes a boundary portion 90 that is positioned at a boundary between the transistor portion 70 and the diode portion 80. It is to be noted that the semiconductor device 100 does not need to include the boundary portion 90.

The boundary portion 90 is a region provided in the transistor portion 70, and is adjacent to the diode portion 80. The boundary portion 90 includes the contact region 15. The boundary portion 90 in the present example does not include the emitter region 12. In an example, the trench portions in the boundary portion 90 are the dummy trench portions 30. The boundary portion 90 in the present example includes the trench portions the dummy trench portions 30 of which are arranged at the both ends in the X axis direction.

The contact hole 54 is provided above the base region 14 in the diode portion 80. The contact hole 54 is provided above the contact region 15 in the boundary portion 90. No contact holes 54 are provided above the well regions 17 provided at the both ends in the Y axis direction.

The mesa portion 91 is provided in the boundary portion 90. The mesa portion 91 includes the contact region 15 in the front surface 21 of the semiconductor substrate 10. The mesa portion 91 in the present example includes the base region 14 and the well region 17 in the negative direction of the Y axis.

The mesa portion 81 is provided in a region sandwiched between the dummy trench portions 30 adjacent to each other in the diode portion 80. The mesa portion 81 includes the contact region 15 at the front surface 21 of the semiconductor substrate 10. The mesa portion 81 in the present example includes the base region 14 and the well region 17 in the negative direction of the Y axis.

The emitter region 12 is provided in the mesa portion 71, but does not need to be provided in the mesa portion 81 and the mesa portion 91. The contact region 15 is provided in the mesa portion 71 and the mesa portion 91, but does not need to be provided in the mesa portion 81.

FIG. 2C shows a b-b′ cross section of a modification example of the semiconductor device 100. This figure corresponds to the b-b′ cross section of FIG. 2B. The semiconductor device 100 in the present example includes the first lifetime control region 151 and a second lifetime control region 152. However, the semiconductor device 100 may not include one of the first lifetime control region 151 or the second lifetime control region 152, and may not include both of the first lifetime control region 151 and the second lifetime control region 152. The semiconductor device 100 of the present example includes a collector region 22 and a cathode region 82 as a back-surface-side region 60.

The contact region 15 is provided above the base region 14 in the mesa portion 91. The contact region 15 is provided in contact with the dummy trench portion 30 in the mesa portion 91. In another cross section, the contact region 15 may be provided at the front surface 21 in the mesa portion 71.

The accumulation region 16 is provided in the transistor portion 70 and the diode portion 80. The accumulation region 16 in the present example is provided at entire surfaces of the transistor portion 70 and the diode portion 80. It is to be noted that the accumulation region 16 does not need to be provided in the diode portion 80.

The cathode region 82 is provided below the buffer region 20 in the diode portion 80. A boundary between the collector region 22 and the cathode region 82 is a boundary between the transistor portion 70 and the diode portion 80. That is, the collector region 22 is provided below the boundary portion 90 in the present example.

The first lifetime control region 151 is provided in both the transistor portion 70 and the diode portion 80. With this configuration, in the semiconductor device 100 in the present example, a recovery speed in the diode portion 80 can be raised, and a switching loss can be further improved. The first lifetime control region 151 may be formed by a method similar to that of the first lifetime control region 151 in other examples.

The second lifetime control region 152 is provided in the front surface 21 side relative to the center of the semiconductor substrate 10 in the depth direction of the semiconductor substrate 10. The second lifetime control region 152 in the present example is provided in the drift region 18. The second lifetime control region 152 is provided in both the transistor portion 70 and the diode portion 80. The second lifetime control region 152 may be formed by implanting an impurity from the front surface 21 side, or may be formed by implanting an impurity from the back surface 23 side. The second lifetime control region 152 may be provided in the diode portion 80 and the boundary portion 90, and does not need to be provided in a part of the transistor portion 70.

The second lifetime control region 152 may be formed by any method among the methods for forming the first lifetime control region 151. Elements, dose amounts, or the like for forming the first lifetime control region 151 and the second lifetime control region 152 may be the same or may be different.

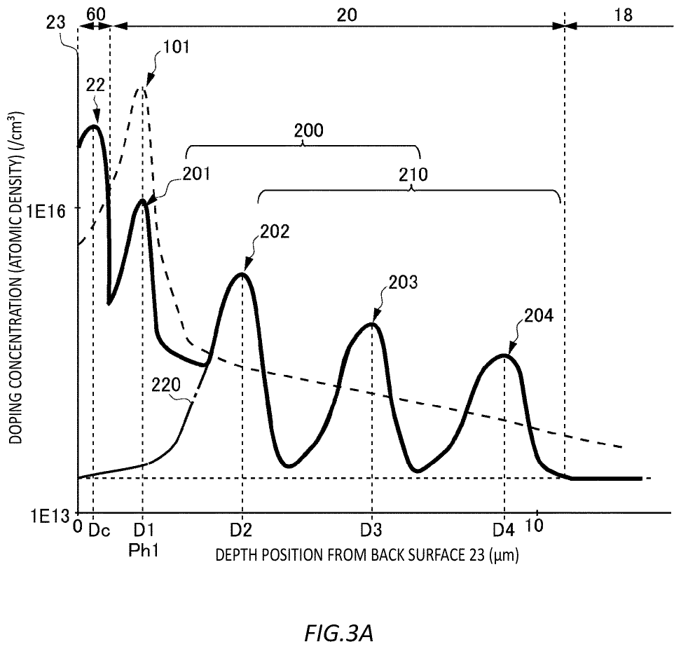

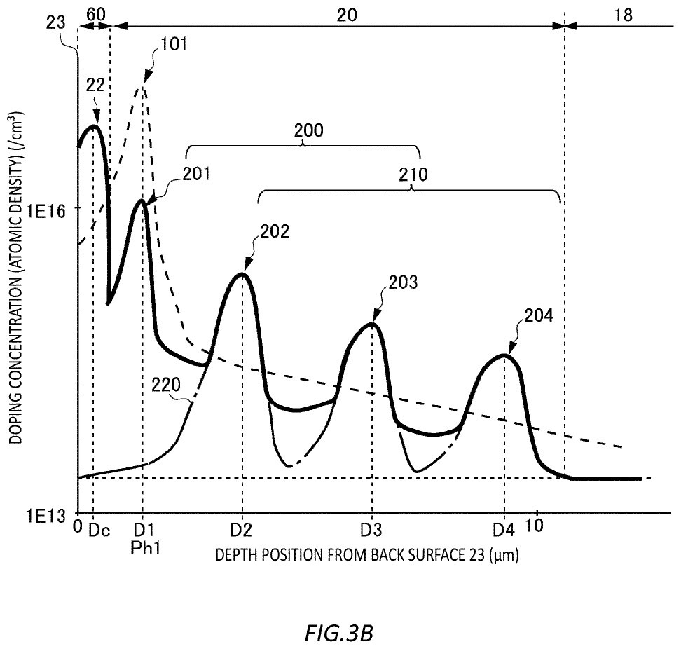

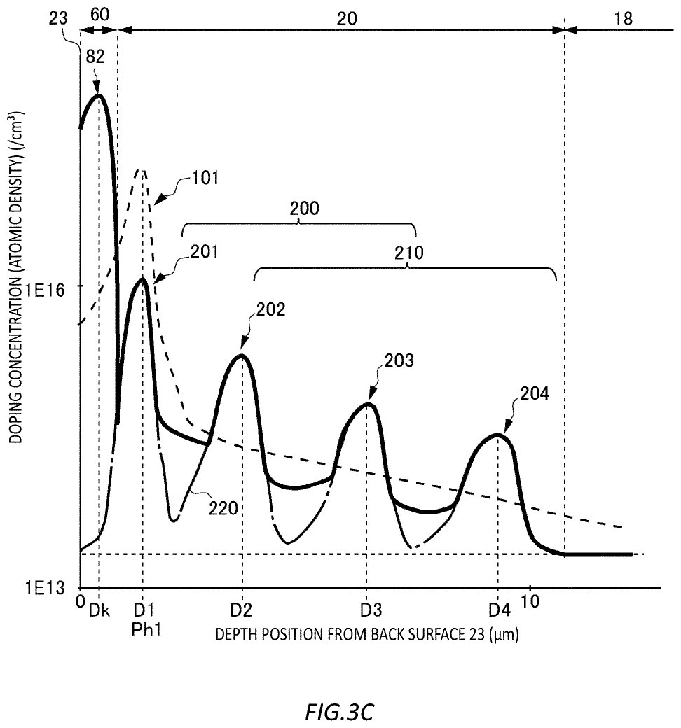

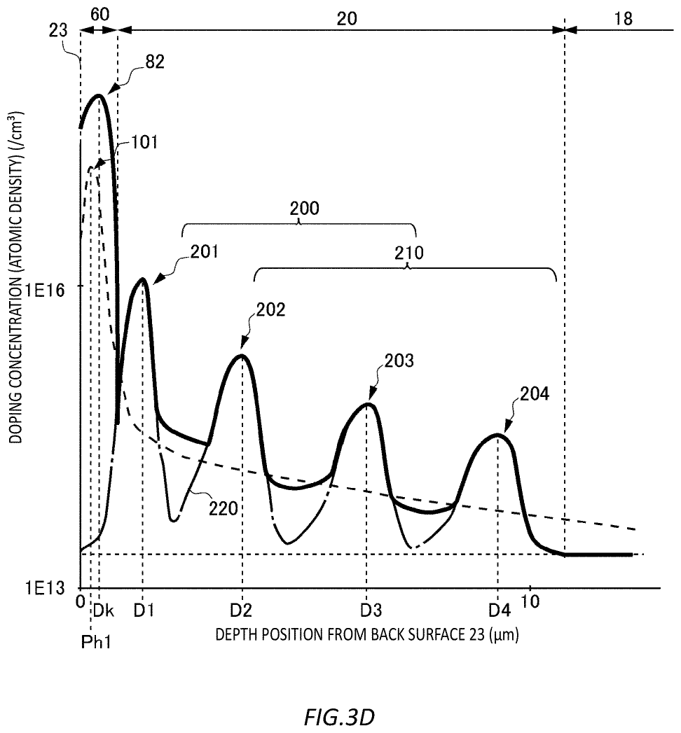

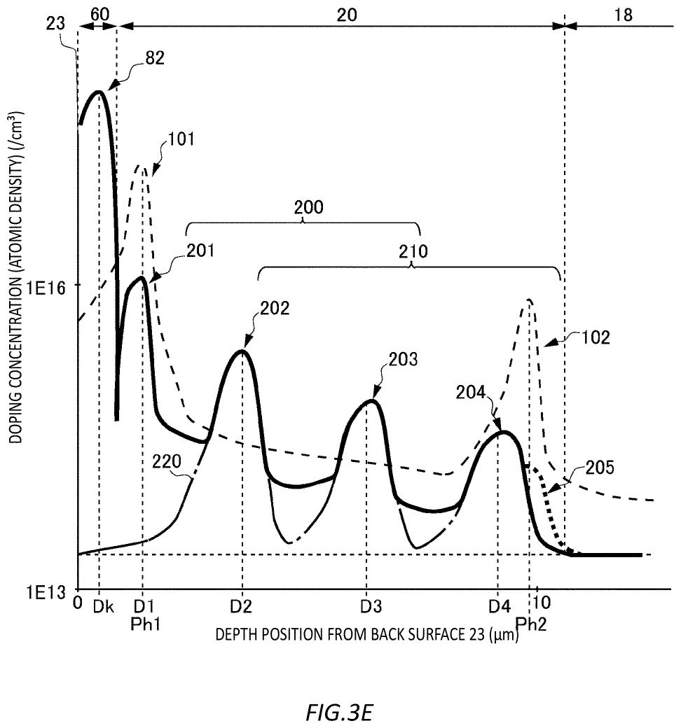

FIG. 3A illustrates an example of a concentration distribution of a doping concentration in a buffer region 20. The buffer region 20 includes a group of concentration peaks 200. The semiconductor substrate 10 of the present example has a first hydrogen peak 101. The solid line graph represents a concentration distribution of a doping concentration in the semiconductor substrate 10. The chain line graph represents a dopant atomic density 220 of the first dopant for forming the group of concentration peaks 200. The dashed line graph represents a distribution of an atomic density of hydrogen. The distributions of the dopant atomic density 220 and the atomic density of hydrogen may be measured using an elemental analysis approach such as SIMS.

The group of concentration peaks 200 includes one or more concentration peaks of doping concentration. The group of concentration peaks 200 of the present example includes four concentration peaks, which are, in order of proximity to the back surface 23 in the depth direction of the semiconductor substrate 10, a first concentration peak 201, a second concentration peak 202, a third concentration peak 203, and a fourth concentration peak 204. The group of concentration peaks 200 may include 2 concentration peaks, 3 concentration peaks, 4 concentration peaks or 5 or more concentration peaks. The group of concentration peaks 200 of the present example includes the first concentration peak 201 and a group of auxiliary peaks 210.

The first concentration peak 201 is provided closest, among one or more concentration peaks in the group of concentration peaks 200, to the back surface 23 of the semiconductor substrate 10 in the depth direction of the semiconductor substrate 10. The depth position D1 is the depth of the first concentration peak 201 from the back surface 23 in the depth direction of the semiconductor substrate 10. Although the first concentration peak 201 of the present example is formed by the ion implantation of hydrogen, it may be formed by ion implantation of N-type dopant such as phosphorous.

The doping concentration of the first concentration peak 201 may be greater than the doping concentration of one or more concentration peaks in the group of auxiliary peaks 210. The first concentration peak 201 of the present example has a greater doping concentration than those of the second concentration peak 202, the third concentration peak 203, or the fourth concentration peak 204. The doping concentration of the first concentration peak 201 may be smaller than the doping concentration of the concentration peak in the back-surface-side region 60. The doping concentration of the first concentration peak 201 may be 1.0E+15 cm⁻³ or more and 1.0E+17 cm⁻³ or less.

The group of auxiliary peaks 210 is provided in the front surface 21 side of the semiconductor substrate 10 relative to the first concentration peak 201 in the depth direction of the semiconductor substrate 10. The group of auxiliary peaks 210 may include one or more concentration peaks other than the first concentration peak 201. The group of auxiliary peaks 210 of the present example includes 3 concentration peaks, which are the second concentration peak 202, the third concentration peak 203, and the fourth concentration peak 204. The group of auxiliary peaks 210 may include one or more concentration peaks formed by ion implantation of a predetermined first dopant other than hydrogen. Although the first dopant of the present example is phosphorous, the first dopant is not limited to this provided it is an N-type dopant.

The first hydrogen peak 101 is a peak of the atomic density of hydrogen. The first hydrogen peak 101 is provided in the same depth position as the depth position D1 of the first concentration peak 201 or may be provided in the back surface 23 side of the semiconductor substrate 10 relative to the depth position D1 of the first concentration peak 201, in the depth direction of the semiconductor substrate 10. The first hydrogen peak 101 may be provided in the back surface 23 side of the semiconductor substrate 10 relative to one or more concentration peaks in the group of auxiliary peaks 210, in the depth direction of the semiconductor substrate 10. The first hydrogen peak 101 may be provided in the front surface 21 side of the semiconductor substrate 10 relative to the concentration peak in the back-surface-side region 60, in the depth direction of the semiconductor substrate 10.

The depth position Ph1 is the depth of the first hydrogen peak 101 from the back surface 23 in the depth direction of the semiconductor substrate 10. The first hydrogen peak 101 of the present example has the same depth position as the depth position D1 of the first concentration peak 201 in the depth direction of the semiconductor substrate 10. That is, the depth position Ph1 is equal to the depth position D1. The depth position Ph1 may be at more than 0 μm and less than 10.0 μm from the back surface 23 of the semiconductor substrate 10 in the depth direction of the semiconductor substrate 10. The depth position Ph1 of the first hydrogen peak 101 may be at more than 0 μm and less than 3.0 μm, less than 5.0 μm, or less than 1.0 μm.

The semiconductor substrate 10 may include a lattice defect. The lattice defect may cause reduction in mobility or lifetime of a charge carrier (electron or positive hole). The mobility or lifetime of the charge carrier may be simply referred to as mobility or lifetime. The atomic density of the first hydrogen peak 101 may be set to a level at which the mobility reduced by the lattice defect can be recovered to a value higher than the reduced value. The atomic density of the first hydrogen peak 101 may be set to a level at which the mobility reduced by the lattice defect can be recovered to a value in the crystalline state. The atomic density of the first hydrogen peak 101 may be set to a level at which the lifetime reduced by the lattice defect can be recovered to a value higher than the reduced value. The atomic density of the first hydrogen peak 101 may be set to a level at which the lifetime reduced by the lattice defect can be recovered to a value in the crystalline state.

The atomic density of the first hydrogen peak 101 may increase to the depth position Ph1 from the back surface 23 and then may decrease gradually toward the front surface 21, in the depth direction of the semiconductor substrate 10. The atomic density of the first hydrogen peak 101 may be 1.0E+16 cm⁻³ or more and 1.0E+20 cm⁻³ or less, or may be 1.0E+17 cm⁻³ or more and 1.0E+19 cm⁻³ or less.

The dopant of the first concentration peak 201 is hydrogen that is ion-implanted for forming the first hydrogen peak 101. The hydrogen attaches to one or more interstitial atoms (silicon in the present example) or to one or more vacancies formed by the ion implantation of hydrogen to form a hydrogen donor. The interstitial atoms and vacancy are one example of the lattice defect. That is, the first concentration peak 201 may be a doping concentration peak of the hydrogen donor. The first concentration peak 201 of the present example is provided in an approximately equal position to the first hydrogen peak 101 in the depth direction of the semiconductor substrate 10. In the present example, the first concentration peak 201 may not overlap with the peak of the dopant atomic density 220 of the first dopant because the dopant of the first concentration peak 201 is not the first dopant. The first hydrogen peak 101 may be provided between the concentration peak in the collector region 22 and the second concentration peak 202, in the depth direction of the semiconductor substrate 10.

Depths of one or more concentration peaks in the group of auxiliary peaks 210 may be 0.5 μm or more and 10.0 μm or less. Depths of one or more concentration peaks in the group of auxiliary peaks 210 may be 1.0 μm or more and 5.0 μm or less.

The depth position D2 of the second concentration peak 202 which is closest, among the one or more concentration peaks in the group of auxiliary peaks 210, to the back surface 23 of the semiconductor substrate 10 in the depth direction of the semiconductor substrate 10 may be at 3.0 μm or more from the back surface 23 of the semiconductor substrate 10. By providing the first hydrogen peak 101, the semiconductor device 100 of the present example can recover the mobility or lifetime which has been reduced due to lattice defect, even if it has the group of auxiliary peaks 210 at the depth position of 3.0 μm or more.

The depth position (depth position D4 in the present example) of the concentration peak which is closest, among the one or more concentration peaks in the group of auxiliary peaks 210, to the front surface 21 of the semiconductor substrate 10 in the depth direction of the semiconductor substrate 10 may be at 10.0 μm or less from the back surface of the semiconductor substrate 10. The depth position D4 is the depth position of the fourth concentration peak 204 from the back surface 23 in the depth direction of the semiconductor substrate 10. The depth position D4 of the fourth concentration peak 204 may be 10.0 μm or less. The depth position D4 of the fourth concentration peak 204 may be provided at a depth position of 10% or more and 20% or less of the substrate thickness of the semiconductor substrate 10, from the back surface 23.

Note that the depth position D3 of the third concentration peak 203 is located between the depth position D2 of the second concentration peak 202 and the depth position D4 of the fourth concentration peak 204 in the depth direction of the semiconductor substrate 10. The depth position D3 of the third concentration peak 203 may be equidistant from the depth position D2 and the depth position D4 in the depth direction of the semiconductor substrate 10. The depth position D3 of the third concentration peak 203 may be closer to the depth position D2 than to the depth position D4, or may be closer to the depth position D4 than to the depth position D2 in the depth direction of the semiconductor substrate 10.

A doping concentration of one or more concentration peaks in the group of auxiliary peaks 210 may be 1.0E+15 cm⁻³ or more and 1.0E+16 cm⁻³ or less. A doping concentration of the group of auxiliary peaks 210 may increase gradually toward the back surface 23 in the depth direction of the semiconductor substrate 10. The doping concentration of the second concentration peak 202 may be greater than the doping concentrations of the third concentration peak 203 and fourth concentration peak 204. The doping concentration of the third concentration peak 203 may be greater than the doping concentration of the fourth concentration peak 204.

The bottoms of the doping concentration in the group of auxiliary peaks 210 of the present example may be substantially equal to those of the dopant atomic density 220 of the first dopant. The term substantially equal may indicate that the doping concentration is within the range of 90% or more and 100% or less of the dopant atomic density. The magnitude of the doping concentration peaks in the group of auxiliary peaks 210 may also be approximately equal to the peaks of dopant atomic density 220. That is, the second concentration peak 202, third concentration peak 203, and fourth concentration peak 204 may each have a substantially equal magnitude of the doping concentration to that of the dopant atomic density 220. However, a doping concentration of the group of auxiliary peaks 210 may be different from the dopant atomic density 220 depending on conditions for activation or the like.

The collector region 22 is an example of back-surface-side region 60. The depth position Dc of the concentration peak of the doping concentration of the collector region 22 may be at more than 0 μm and less than 0.5 μm from the back surface 23 of the semiconductor substrate 10 in the depth direction of the semiconductor substrate 10. The doping concentration of the concentration peak in the collector region 22 may be 1.0E+15 cm⁻³ or more and 1.0E+18 cm⁻³ or less. Note that although the back-surface-side region 60 is described as being the collector region 22 in the present example, the back-surface-side region 60 may be a cathode region 82.

Since the semiconductor device 100 of the present example has the first hydrogen peak 101 in the back surface 23 side relative to the group of auxiliary peaks 210 in the depth direction of the semiconductor substrate 10, the hydrogen can terminate the dangling bond in the lattice defect or the like, allowing recovery of the mobility or lifetime that has been reduced due to the lattice defect of the semiconductor substrate 10. Accordingly, the electrical property of the semiconductor device 100 can be enhanced by improving mobility and suppressing the reduction of the lifetime of the semiconductor substrate 10.

Here, the first dopant other than hydrogen is less likely affected by the oxygen concentration or carbon concentration of the semiconductor substrate 10 when being activated. By forming the group of auxiliary peaks 210 by ion implantation of the first dopant, the semiconductor device 100 of the present example can provide a buffer region 20 that is less affected by oxygen concentration or carbon concentration in the semiconductor substrate 10. The semiconductor device 100 of the present example can suppress the influence of oxygen concentration or carbon concentration even when the semiconductor substrate 10 used is the one having higher oxygen concentration or carbon concentration formed by CZ method (Czochralski method) or MCZ method (magnetic field applied Czochralski method) than the semiconductor substrate 10 formed by the FZ (floating zone) method.

Note that, apart from ion-implanted phosphorous as the first dopant, phosphorous or antimony may remain in the semiconductor substrate 10. The semiconductor substrate 10 may be doped with boron at a lower doping concentration than that of phosphorous and antimony.

FIG. 3B illustrates a modification example of a concentration distribution of a doping concentration in a buffer region 20. In the present example, doping concentrations at the bottoms in the group of auxiliary peaks 210 are different from the example of FIG. 3A. In the present example, points different from those of the example shown in FIG. 3A will be described in particular. Note that although the back-surface-side region 60 is described as being the collector region 22 in the present example, the back-surface-side region 60 may be a cathode region 82.

The bottoms of the doping concentration in the group of auxiliary peaks 210 of the present example may be higher than those of the dopant atomic density 220 of the first dopant. The magnitude of the doping concentration peaks in the group of auxiliary peaks 210 may be approximately equal to the peaks of the dopant atomic density 220. That is, the second concentration peak 202, third concentration peak 203, and fourth concentration peak 204 may each have approximately equal magnitude of doping concentration to those of the dopant atomic density 220.

By having the first hydrogen peak 101, the semiconductor device 100 of the present example recovers the mobility or lifetime which has been reduced due to the lattice defect of the semiconductor substrate 10. Moreover, in the semiconductor device 100, the doping concentration of the semiconductor substrate 10 may be increased by the presence of oxygen or carbon in the semiconductor substrate 10 in addition to the formation of the first hydrogen peak 101 in the semiconductor substrate 10. For example, due to the formation of defect complex in which at least two or more factors of vacancies (V) or interstitial atoms (in the present example, interstitial silicon), oxygen (O), carbon (C), and hydrogen (H) present in the semiconductor are combined, a hydrogen donor is formed and the values of the bottom portions of the doping concentration may be added to the values of the bottom portion of the doping concentration of the first dopant.

FIG. 3C illustrates a modification example of concentration distribution of a doping concentration in a buffer region 20. The present example is different from the example in FIG. 3B in that the peak of the dopant atomic density 220 is formed at approximately the same position as the first concentration peak 201. Note that although the semiconductor device 100 of the present example includes a cathode region 82 as a back-surface-side region 60, it may include a collector region 22. In the present example, points different from the example of FIG. 3B will be particularly described.

The dopant of the first concentration peak 201 is hydrogen and the first dopant that is ion-implanted for forming the first hydrogen peak 101. That is, the first concentration peak 201 may be a peak that represents the sum of the doping concentration of the hydrogen donor resulted from the ion-implanted hydrogen becoming a donor and the doping concentration of a donor resulted from the ion-implanted first dopant becoming a donor. The first concentration peak 201 of the present example is provided at an approximately equal position to the peak of the dopant atomic density 220 of the first hydrogen peak 101 in the depth direction of the semiconductor substrate 10. The dopant atomic density 220 of the present example has four peaks at the depth positions corresponding to four peaks of the doping concentration in the group of concentration peaks 200.

The cathode region 82 is an example of the back-surface-side region 60. The depth position Dk of the concentration peak of the doping concentration of the cathode region 82 may be at more than 0 μm and less than 1.0 μm from the back surface 23 of the semiconductor substrate 10 in the depth direction of the semiconductor substrate 10. Doping concentrations of the concentration peak in the cathode region 82 may be 1.0E+18 cm⁻³ or more and 1.0E+20 cm⁻³ or less. Note that although the back-surface-side region 60 is described as being the cathode region 82 in the present example, the back-surface-side region 60 may be a collector region 22.

FIG. 3D illustrates a modification example of the concentration distribution of a doping concentration in a buffer region 20. The present example is different from the example of FIG. 3B in the depth position of the first hydrogen peak 101. In the present example, points different from the example of FIG. 3B will be particularly described. Note that although the semiconductor device 100 of the present example includes a cathode region 82 as a back-surface-side region 60, it may include a collector region 22.

The dopant of the first concentration peak 201 is the first dopant. That is, the peak of the dopant atomic density 220 is formed at the depth position corresponding to the first concentration peak 201. The dopant atomic density 220 of the present example has four peaks at the depth positions corresponding to four peaks of the doping concentration in the group of concentration peaks 200.

On the other hand, the first hydrogen peak 101 may be provided spaced apart from the first concentration peak 201 in the depth direction of the semiconductor substrate 10. The first hydrogen peak 101 may be provided in the back surface 23 side of the semiconductor substrate 10 relative to the concentration peak in the back-surface-side region 60 in the depth direction of the semiconductor substrate 10. That is, the depth position D1 of the first concentration peak 201 may be greater than the depth position Ph1 of the first hydrogen peak 101. Moreover, the first hydrogen peak 101 may be arranged apart from the first concentration peak 201 so that it is provided outer side relative to the half-value width of the first concentration peak 201 in the depth direction of the semiconductor substrate 10.

FIG. 3E illustrates a modification example of concentration distribution of a doping concentration in a buffer region 20. The present example is different from the example of FIG. 3B in that the semiconductor substrate 10 has the first hydrogen peak 101 and the second hydrogen peak 102. In the present example, points different from the example of FIG. 3B will be particularly described. Note that although the back-surface-side region 60 is described as being the cathode region 82 in the present example, the back-surface-side region 60 may be a collector region 22.

The second hydrogen peak 102 is provided in the front surface 21 side of the semiconductor substrate 10 relative to the first hydrogen peak 101 in the depth direction of the semiconductor substrate 10. The second hydrogen peak 102 may be provided in the front surface 21 side of the semiconductor substrate 10 relative to the concentration peak that is closest, among one or more concentration peaks of the group of auxiliary peaks 210, to the front surface 21 of the semiconductor substrate 10, in the depth direction of the semiconductor substrate 10. That is, the second hydrogen peak 102 of the present example is provided in the front surface 21 side relative to the fourth concentration peak 204 in the depth direction of the semiconductor substrate 10. The depth position Ph2 of the second hydrogen peak 102 may be greater than the depth position D4 of the fourth concentration peak 204.

Note that the second hydrogen peak 102 may be provided in the back surface 23 side relative to the peak (the fourth concentration peak 204 in the present example) of the first dopant located closest to the front surface 21. That is, the peak of the first dopant that is located closest to the front surface 21 may be located in the front surface 21 side relative to the second hydrogen peak.

The second hydrogen peak 102 may be provided between the concentration peak that is closest, among one or more concentration peaks of the group of auxiliary peaks 210, to the front surface 21 of the semiconductor substrate 10, and the drift region 18 in the depth direction of the semiconductor substrate 10. That is, the second hydrogen peak 102 of the present example is provided between the fourth concentration peak 204 and the drift region 18 in the depth direction of the semiconductor substrate 10. By providing the second hydrogen peak 102, the lattice defect in a region further away from the back surface 23 to which laser-annealing is difficult to reach can be recovered to be the crystalline state more easily.

The atomic density of the second hydrogen peak 102 may be less than the atomic density of the first hydrogen peak 101. The atomic density of the second hydrogen peak 102 may be 1.0E+14 cm⁻³ or more and 1.0E+19 cm⁻³ or less, or may be 1.0E+15 cm⁻³ or more and 1.0E+18 cm⁻³ or less. The depth position Ph2 of the second hydrogen peak 102 may be 5.0 μm or more, 8.0 μm or more, and 10.0 μm or more. The depth position Ph2 of the second hydrogen peak 102 may be 20.0 μm or less, 15.0 μm or less, and 10.0 μm or less. Note that, as shown by a dotted line, the concentration distribution of the doping concentration may have an additional peak 205 of the doping concentration corresponding to the second hydrogen peak 102. The additional peak 205 may be lower than the fourth concentration peak 204. The additional peak 205 may be omitted.

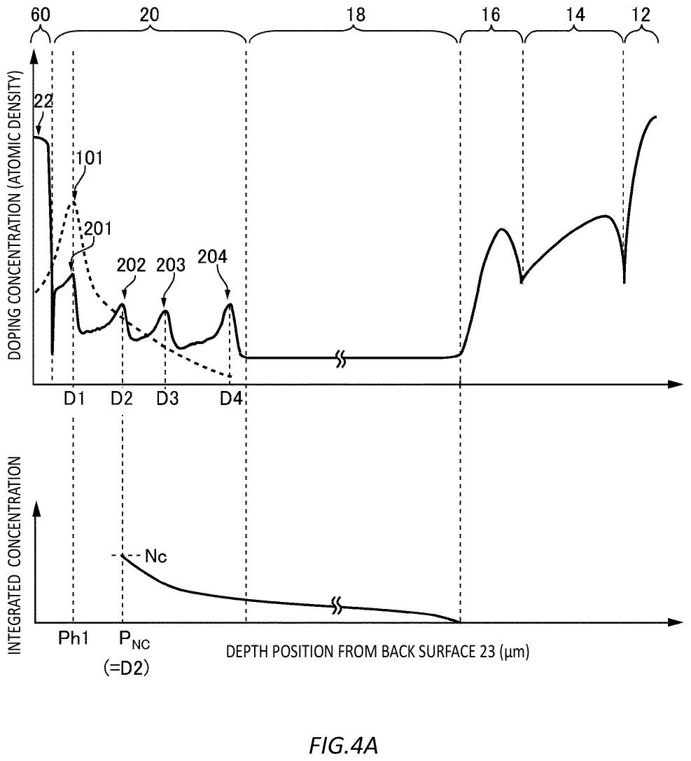

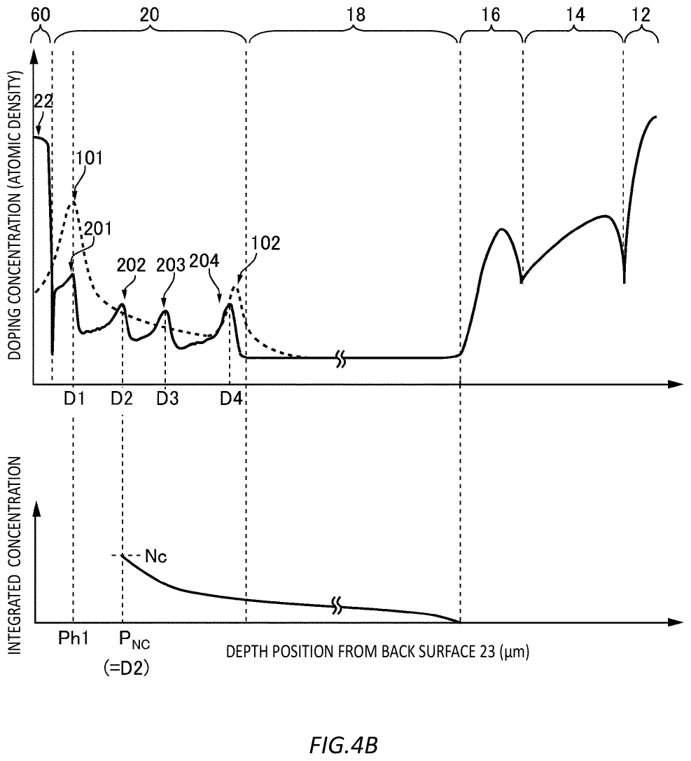

FIG. 4A illustrates an example of doping concentration distribution in a semiconductor substrate 10. The present drawing also shows the atomic density distribution of the first hydrogen peak 101. In addition, the present drawing illustrates an integrated concentration from an upper end of the drift region 18 too.

In the present specification, a value obtained by integrating the doping concentration from the upper end of the drift region 18 to a particular position in the semiconductor substrate 10 along the depth direction of the semiconductor substrate 10 is referred to as an integrated concentration. When a forward bias voltage is applied between the collector electrode 24 and the emitter electrode 52, a depletion layer extends in the depth direction from the lower surface of the base region 14 to the drift region 18. When the applied voltage is increased and the maximum value of the electric field intensity in the depletion layer reaches the critical electric field intensity, avalanche breakdown occurs. Assuming that the end of the depletion layer located in the back surface 23 side when the avalanche breakdown occurs is the particular position, the integrated concentration obtained by integrating the doping concentration from the upper end of the drift region 18 to the particular position is referred to as a critical integrated concentration Nc.

Note that in the semiconductor device 100, a forward bias voltage being applied between the collector electrode 24 and the emitter electrode 52 means that the potential in the collector electrode 24 is higher than the potential in the emitter electrode 52 when the gate is in the off state. When avalanche breakdown has occurred in the semiconductor device 100, an avalanche current flows between the collector electrode 24 and the emitter electrode 52, and an increase in a voltage V_{CE} between the collector electrode 24 and the emitter electrode 52 stops. In this case, the depletion layer does not extend onto the back surface 23 side relative to the position P_{Nc} at which the integrated concentration reaches the critical integrated concentration Nc.

The integrated concentration obtained by integrating the doping concentration from the upper end of the drift region 18 towards the back surface 23 side of the semiconductor substrate 10 in the depth direction of the semiconductor substrate 10 may reach the critical integrated concentration in the buffer region 20. In the present example, the integrated concentration from the upper end of the drift region 18 to the second concentration peak 202 in the depth direction of the semiconductor substrate 10 may be equal to or more than the critical integrated concentration Nc. The position P_{Nc} at which the critical integrated concentration Nc is reached may be identical to the depth position D2 of the second concentration peak 202. That is, the depletion layer extending from the lower surface side of the base region 14 may be stopped by the second concentration peak 202. However, the depletion layer extending from the lower surface side of the base region 14 may be stopped by another concentration peak such as the first concentration peak 201, third concentration peak 203, or fourth concentration peak 204.

The first hydrogen peak 101 may be provided in the back surface 23 side of the semiconductor substrate 10 relative to the depth position at which the integrated concentration reaches the critical integrated concentration Nc in the depth direction of the semiconductor substrate 10. That is, the first hydrogen peak 101 may be provided in the back surface 23 side relative to the concentration peak in the buffer region 20 that stops the depletion layer. The first hydrogen peak 101 of the present example is provided in the back surface 23 side relative to the second concentration peak 202.

The position P_{Nc} at which the critical integrated concentration Nc is reached and the peak position of the buffer region 20 (the depth position D2 of the second concentration peak 202 in the present example) may not be identical. The position P_{Nc} at which the critical integrated concentration Nc is reached may be located between the first concentration peak 201 and the second concentration peak 202, between the second concentration peak 202 and the third concentration peak 203, or between the third concentration peak 203 and the fourth concentration peak 204.

FIG. 4B illustrates an example of doping concentration distribution in a semiconductor substrate 10 as a modification example. The semiconductor substrate 10 of the present example is different from the example of FIG. 4A in that it has the second hydrogen peak 102. That is, the semiconductor device 100 of the present example corresponds to the example of FIG. 3E.

The second hydrogen peak 102 is provided in the front surface 21 side relative to the first hydrogen peak 101 in the depth direction of the semiconductor substrate 10. In the depth direction of the semiconductor substrate 10, one or more peaks of the first dopant may be provided between the first hydrogen peak 101 and the second hydrogen peak 102. The semiconductor device 100 of the present example is provided with the second concentration peak 202, third concentration peak 203, and fourth concentration peak 204 between the first hydrogen peak 101 and the second hydrogen peak 102 in the depth direction of the semiconductor substrate 10.

The second hydrogen peak 102 may be provided in the front surface 21 side of the semiconductor substrate 10 relative to the depth position at which the integrated concentration reaches the critical integrated concentration Nc in the depth direction of the semiconductor substrate 10. That is, the second hydrogen peak 102 may be provided in the front surface 21 side relative to the concentration peak in the buffer region 20 that stops the depletion layer. The atomic density of the second hydrogen peak 102 of the present example is lower than the atomic density of the first hydrogen peak 101. However, the atomic density of the second hydrogen peak 102 may be the same as or greater than the atomic density of the first hydrogen peak 101.

The second hydrogen peak 102 may be provided in the front surface 21 side relative to the peak of the first dopant that is located closest to the front surface 21 in the depth direction of the semiconductor substrate 10. The second hydrogen peak 102 of the present example is provided in the front surface 21 side relative to the fourth concentration peak 204 in the depth direction of the semiconductor substrate 10. However, in the depth direction of the semiconductor substrate 10, the second hydrogen peak 102 may be provided in the back surface 23 side relative to the peak of the first dopant that is located closest to the front surface 21. In other words, in the depth direction of the semiconductor substrate 10, the peak of the first dopant that is located closest to the front surface 21 may be located in the front surface 21 side relative to the second hydrogen peak 102.

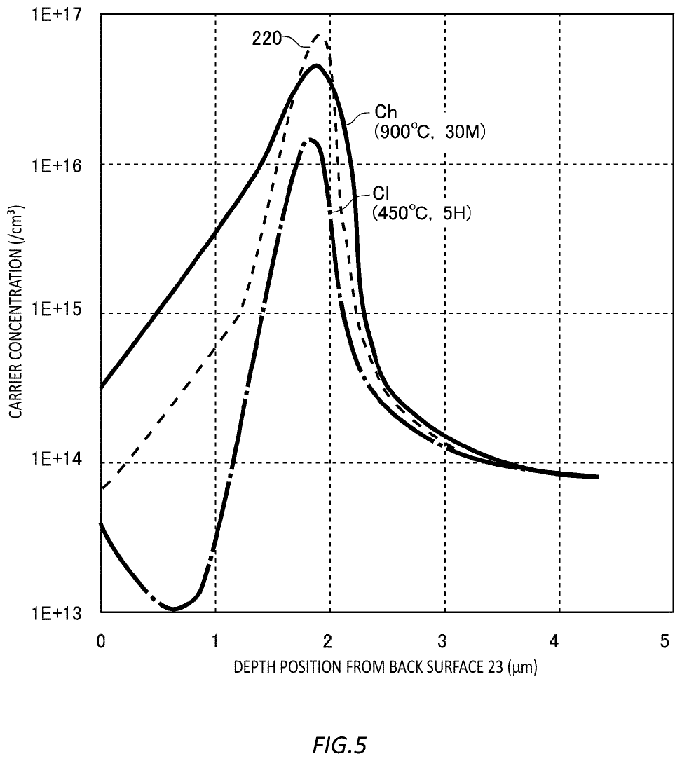

FIG. 5 is a drawing to describe a difference in a degree of activation according to an annealing temperature. The vertical axis represents a carrier concentration obtained by SR measurement. The dopant atomic density 220 shows the atomic density of phosphorous before annealing. The solid line graph Ch shows the doping concentration of phosphorous after annealing the semiconductor substrate 10 at the high temperature of 900° C. for 30 minutes. The chain line graph Cl shows the doping concentration of phosphorous after annealing the semiconductor substrate 10 at the low temperature of 450° C. for 5 hours.

It can be seen that the graph Ch which represents annealing at a relatively high temperature exhibits higher doping concentration and higher level of activation than the graph CI which represents annealing at a low temperature. That is, under such a temperature as being employed for annealing the buffer region 20 (for example, 450° C.), activation of the dopant or recovery of mobility and lifetime may be insufficient. On the other hand, annealing the semiconductor substrate 10 at a high temperature after structures are formed on the front surface 21 side may be difficult, considering refined manufacturing processes of the semiconductor device 100. For example, if a material, such as tungsten, which melts at a high temperature is used in the front surface 21 side, high-temperature annealing for forming the structures in the back surface 23 side is difficult.

Meanwhile, when the semiconductor device 100 includes the first hydrogen peak 101, the hydrogen contributes to the recovery of mobility and lifetime without high-temperature annealing of the semiconductor substrate 10. Accordingly, in addition to activation of the buffer region 20, recovery of mobility and lifetime can be achieved.

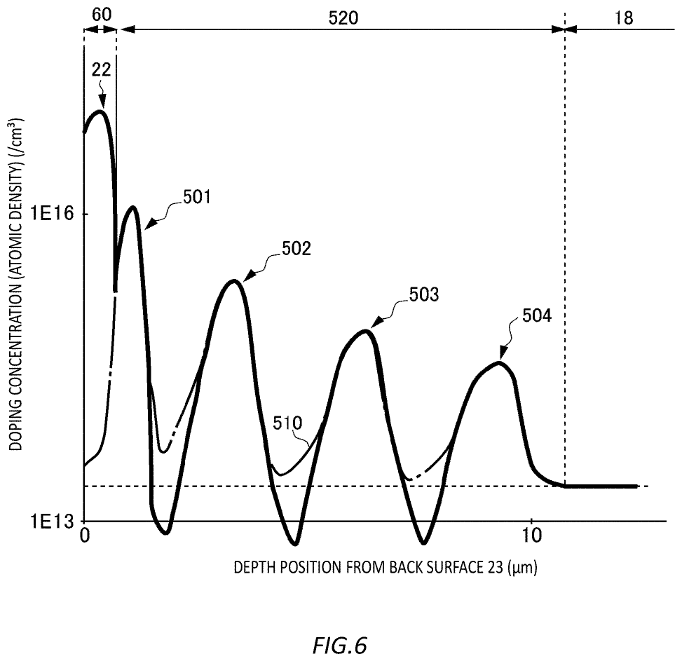

FIG. 6 is an example of distribution of a doping concentration in a buffer region 520 as a comparative example. The buffer region 520 includes four concentration peaks, which are the first concentration peak 501, second concentration peak 502, third concentration peak 503, and fourth concentration peak 504. However, the buffer region 520 does not include a hydrogen concentration peak. Therefore, the activation or recovery is insufficient in the bottom regions of the doping concentration of the buffer region 520, and the doping concentration is decreased below the dopant atomic density 510.

If the activation or recovery is insufficient, the mobility of the carrier may be reduced and thus the electrical property of the semiconductor device may be degraded. Moreover, in the region in which the activation by laser-annealing is difficult, some lattice defects may remain unrecovered.

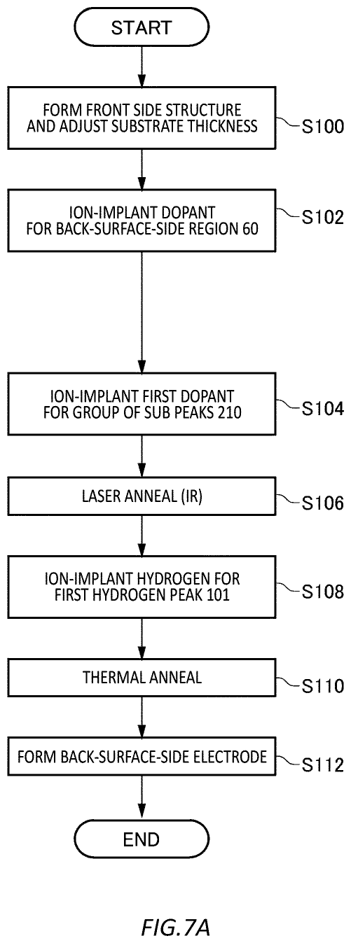

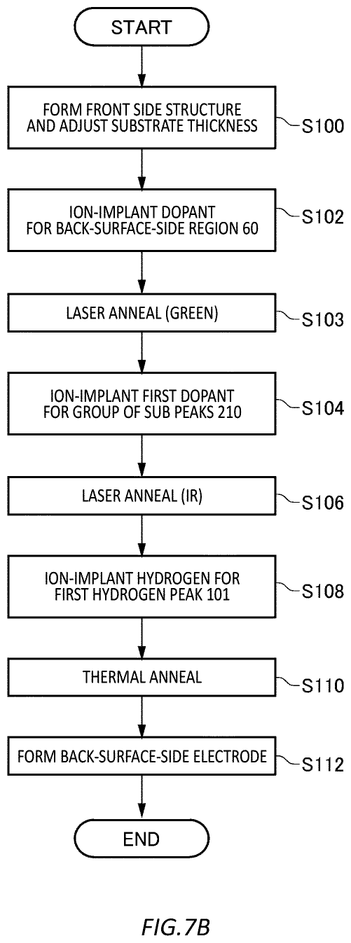

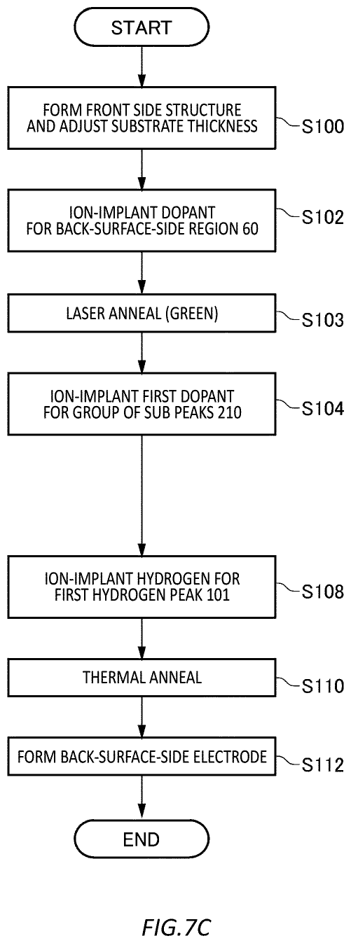

FIG. 7A is a flowchart showing an example of a manufacturing process of the semiconductor device 100. In step S100, a structure in the front surface 21 side of the semiconductor device 100 is formed. Moreover, in step S100, after the structure in the front surface 21 side is formed, the thickness of the semiconductor substrate 10 may be adjusted according to the required breakdown voltage by grinding the back surface 23 side of the semiconductor substrate 10.

In step S102, the dopant for forming the back-surface-side region 60 is ion-implanted from the back surface 23 side of the semiconductor substrate 10. The back-surface-side region 60 may be formed on the whole back surface 23 of the semiconductor substrate 10. Ion implantation may be performed so that the back-surface-side region 60 includes the concentration peak of a doping concentration in the back surface 23 side of the semiconductor substrate 10 relative to the drift region 18 in the depth direction of the semiconductor substrate 10. When the back-surface-side region 60 is the collector region 22, the dopant may be boron. When the back-surface-side region 60 is the cathode region 82, the dopant may be phosphorous. When the back-surface-side region 60 includes both the collector region 22 and the cathode region 82, the dopant for the collector region 22 and the dopant for the cathode region 82 may be separately ion-implanted into each region.

The ion dose amount for forming the collector region 22 may be equal to or greater than 1.0E+12/cm² and equal to or less than 1.0E+15/cm². The ion dose amount for forming the cathode region 82 may be equal to or greater than 1.0E+14/cm² and equal to or less than 1.0E+16/cm².

In step S104, the first dopant for the group of auxiliary peaks 210 is ion-implanted. When the dopant of the first concentration peak 201 includes the first dopant, the first dopant may also be ion-implanted into the depth position corresponding to the first concentration peak 201 in addition to the group of auxiliary peaks 210. Although in the present example, the first dopant of the group of auxiliary peaks 210 is ion-implanted after the dopant for forming the back-surface-side region 60 is ion-implanted, the first dopant of the group of auxiliary peaks 210 may be ion-implanted before the dopant for the back-surface-side region 60 is ion-implanted.

In step S106, the semiconductor substrate 10 is laser-annealed from the back surface 23 side of the semiconductor substrate 10. That is, the semiconductor substrate 10 is laser-annealed after ion-implanting the first dopant into the semiconductor substrate 10 for forming the group of auxiliary peaks 210 (step S104). Although in the present example, the semiconductor substrate 10 is laser-annealed using the infrared ray (IR) laser, it is not limited to this. The IR laser may be a laser that has a wavelength of more than 780 nm and may have a wavelength of 1064 nm in one example.

In step S108, hydrogen for forming the first hydrogen peak 101 is ion-implanted into the semiconductor substrate 10. The hydrogen may be ion-implanted from the back surface 23 side of the semiconductor substrate 10. In step S108, in addition to the hydrogen for forming the first hydrogen peak 101, hydrogen for forming the second hydrogen peak 102 may be ion-implanted.

In step S110, the semiconductor substrate 10 is thermal-annealed after hydrogen is ion-implanted. By performing the thermal annealing after the ion implantation of hydrogen into the semiconductor substrate 10, the hydrogen spreads in the depth direction of the semiconductor substrate 10 and facilitates activation of the dopant in the buffer region 20. The thermal annealing may be the furnace annealing which heats the semiconductor device 100 in the furnace. The temperature of the thermal annealing may be 300° C. or more and 500° C. or less, or 350° C. or more and 450° C. or less. For example, the temperature of the thermal annealing is 370° C. The duration of the thermal annealing may be five hours.

In step S112, the back-surface-side electrode is formed. The back-surface-side electrode may be a collector electrode 24 or a cathode electrode. For example, the back-surface-side electrode is formed by the sputtering method. The back-surface-side electrode may be a laminated electrode in which an aluminum layer, titanium layer, and nickel layer or the like are laminated. In accordance with such a process, the semiconductor device 100 can be manufactured.

Here, in the laser annealing that uses an IR laser, it may be difficult to activate a region, such as the back-surface-side region 60, that is shallower than the buffer region 20. The semiconductor device 100 of the present example includes the first hydrogen peak 101 and thus allows the hydrogen to interact with the residual defect in the substrate to turn the residual defect into a donor. Accordingly, the back-surface-side region 60 can be activated by the thermal annealing even if the laser annealing by the green laser is omitted.

The present example may not include the step to laser-anneal the semiconductor substrate 10 after the step (step S102) to form the back-surface-side region 60 and before the step (step S104) to ion-implant the first dopant into the semiconductor substrate 10 for formation of the group of auxiliary peaks 210. In this manner, even if a laser annealing process dedicated to forming the back-surface-side region 60 (for example, laser annealing by green laser) is not employed, the back-surface-side region 60 can be activated by the thermal annealing that is performed after the formation of the first hydrogen peak 101.

Note that, if any other region such as the first lifetime control region 151 is formed in the back surface 23 side of the semiconductor substrate 10, an appropriate process for forming such a region may be added accordingly.

FIG. 7B is a flowchart showing a modification example of the manufacturing process of the semiconductor device 100. The present example is different from the example of FIG. 7A in that the semiconductor substrate 10 is laser-annealed to form the back-surface-side region 60. In the present example, points different from those of the example shown in FIG. 7A will be described in particular.

In step S103, the semiconductor substrate 10 is laser-annealed. That is, the present example includes the step to laser-anneal the semiconductor substrate 10 after the step (step S102) to form the back-surface-side region 60 and before the step (step S104) to ion-implant the first dopant into the semiconductor substrate 10 for formation of the group of auxiliary peaks 210. Although in the present example, the semiconductor substrate 10 is laser-annealed using the green laser, it is not limited to this. In step S102, by laser-annealing the semiconductor substrate 10 after the dopant for forming the back-surface-side region 60 is ion-implanted, the depth position at which the back-surface-side region 60 is formed can be selectively activated.

A type of green laser employed for annealing the back-surface-side region 60 is not particularly limited. Although the laser employed for annealing the back-surface-side region 60 may be the YAG2ω laser (wavelength 532 nm) which is a solid-state laser, it is not limited to this.

Note that, the step for forming the back-surface-side region 60 may not include the thermal annealing for forming the back-surface-side region 60. That is, the recovery of a defect and activation of a dopant in the back-surface-side region 60 may be achieved only by laser annealing. However, the recovery of a defect and activation of a dopant in the back-surface-side region 60 may be achieved by thermal annealing in combination with laser annealing.

Here, although the energy density needs to be increased in order to activate a deeper region (for example, at 3 μm or more from the back surface 23) in the buffer region 20, it would exceed a melting threshold of semiconductor substrate 10, and thus activating the buffer region 20 by laser annealing may be difficult. The semiconductor device 100 of the present example includes the first hydrogen peak 101, allowing the residual defect to turn into a donor by hydrogen. Accordingly, the deeper region in the buffer region 20 can be activated.

FIG. 7C is a flowchart showing a modification example of the manufacturing process of the semiconductor device 100. The present example is different from the example in FIG. 7B in that the laser-annealing process for forming the group of auxiliary peaks 210 is not included. In the present example, points different from the example of FIG. 7B will be particularly described.

The present example includes a step (step S108) to ion-implant hydrogen into the semiconductor substrate 10 for forming the first hydrogen peak 101 after the step (step S104) to ion-implant the first dopant into the semiconductor substrate 10 for forming the group of auxiliary peaks 210. In step S110, the semiconductor substrate 10 is thermal-annealed after the ion implantation of hydrogen. That is, the step to laser-anneal the semiconductor substrate 10 is not included after the step (step S104) to ion-implant the first dopant into the semiconductor substrate 10 and before the step (step S108) to ion-implant hydrogen into the semiconductor substrate 10. That is, the laser annealing by the IR laser for forming the group of auxiliary peaks 210 is not needed. If the laser annealing by the IR laser is omitted, the activation may further be facilitated by forming the second hydrogen peak 102 in the front surface 21 side relative to the group of auxiliary peaks 210 in addition to the first hydrogen peak 101.

In this manner, by forming the first hydrogen peak 101 or the second hydrogen peak 102, the buffer region 20 becomes more easily activated, and thus the activation of the buffer region 20 can be achieved by thermal annealing without laser annealing. Although in the present example, the semiconductor substrate 10 is laser-annealed by the green laser for forming the back-surface-side region 60 in step S103, this laser-annealing process may be omitted.

As described above, the manufacturing method of the present example is capable of activating both the back-surface-side region 60 and the buffer region 20 by selectively using the green laser and the IR laser. Determination to omit or not to omit laser annealing may be made depending on the depth of one or more peaks in the buffer region 20 or depending on conditions for the hydrogen peaks to be formed. The manufacturing process can be simplified by selecting a suitable manufacturing method according to the configuration of the semiconductor device 100 to be manufactured.

While the present invention has been described by way of the embodiments, the technical scope of the present invention is not limited to the above-described embodiments. It is apparent to persons skilled in the art that various modifications or improvements can be made to the above-described embodiments. It is also apparent from the description of the claims that embodiments added with such alterations or improvements can be included in the technical scope of the present invention.

The operations, procedures, steps, and stages of each process performed by an apparatus, system, program, and method illustrated in the claims, specifications, or drawings can be performed in any order as long as the order is not indicated by “prior to,” “before,” or the like and as long as the output from a previous process is not used in a later process. Even if the operation flow is described by using phrases such as “first” or “next” in the scope of the claims, specification, or drawings, it does not necessarily mean that the process must be performed in this order.

### EXPLANATION OF REFERENCES

10 . . . semiconductor substrate, 12 . . . emitter region, 14 . . . base region, 15 . . . contact region, 16 . . . accumulation region, 17 . . . well region, 18 . . . drift region, 20 . . . buffer region, 21 . . . front surface, 22 . . . collector region, 23 . . . back surface, 24 . . . collector electrode, 25 . . . connection section, . . . 30 . . . dummy trench portion, 31 . . . extending portion, 32 . . . dummy dielectric film, 33 . . . connecting portion, 34 . . . dummy conductive portion, 38 . . . interlayer dielectric film, 40 . . . gate trench portion, 41 . . . extending portion, 42 . . . gate dielectric film, 43 . . . connecting portion, 44 . . . gate conductive portion, 50 . . . gate metal layer, 52 . . . emitter electrode, 54 . . . contact hole, 55 . . . contact hole, 56 . . . contact hole, 60 . . . back-surface-side region, 70 . . . transistor portion, 71 . . . mesa portion, 80 . . . diode portion, 81 . . . mesa portion, 82 . . . cathode region, 85 . . . extension region, 90 . . . boundary portion, 91 . . . mesa portion, 100 . . . semiconductor device, 101 . . . first hydrogen peak, 102 . . . second hydrogen peak, 105 . . . end side, 112 . . . gate pad, 120 . . . active section, 130 . . . outer circumferential gate runner, 131 . . . active-side gate runner, 140 . . . edge termination structure portion, 151 . . . first lifetime control region, 152 . . . second lifetime control region, 200 . . . group of concentration peaks, 201 . . . first concentration peak, 202 . . . second concentration peak, 203 . . . third concentration peak, 204 . . . fourth concentration peak, 205 . . . additional peak, 210 . . . group of auxiliary peaks, 220 . . . dopant atomic density, 501 . . . first concentration peak, 502 . . . second concentration peak, 503 . . . third concentration peak, 504 . . . fourth concentration peak, 510 . . . dopant atomic density, 520 . . . buffer region.

What is claimed is:

1. A semiconductor device comprising:
a drift region of a first conductivity type provided in a semiconductor substrate having a front surface and a back surface; and
a buffer region of a first conductivity type provided a back surface side of the semiconductor substrate relative to the drift region in a depth direction of the semiconductor substrate, the back surface side being a side of the back surface, wherein
the buffer region has a group of concentration peaks including one or more concentration peaks of a doping concentration,
the group of concentration peaks includes a first concentration peak that is provided closest, among the one or more concentration peaks, to the back surface of the semiconductor substrate in the depth direction of the semiconductor substrate, and
the semiconductor substrate includes a first hydrogen peak which is a peak of an atomic density of hydrogen, provided in a same depth position as a depth position of the first concentration peak or in the back surface side of the semiconductor substrate relative to a depth position of the first concentration peak in the depth direction of the semiconductor substrate.

2. The semiconductor device according to claim 1, wherein
the group of concentration peaks includes a group of auxiliary peaks provided in a front surface side of the semiconductor substrate relative to the first concentration peak in the depth direction of the semiconductor substrate, the front surface side being a side of the front surface, and
the group of auxiliary peaks includes one or more concentration peaks having a first dopant predetermined other than hydrogen.

3. The semiconductor device according to claim 2, wherein
a doping concentration of the one or more concentration peaks in the group of auxiliary peaks is 1.0E+15 cm⁻³ or more and 1.0E+16 cm⁻³ or less.

4. The semiconductor device according to claim 2, wherein
the first hydrogen peak is provided in the back surface side of the semiconductor substrate relative to the one or more concentration peaks of the group of auxiliary peaks in the depth direction of the semiconductor substrate.

5. The semiconductor device according to claim 2, wherein
a dopant of the first concentration peak is the hydrogen.

6. The semiconductor device according to claim 2, wherein
a dopant of the first concentration peak is the first dopant.

7. The semiconductor device according to claim 2, wherein
a dopant of the first concentration peak is the hydrogen and the first dopant.

8. The semiconductor device according to claim 2, wherein
a depth of the one or more concentration peaks in the group of auxiliary peaks is 0.5 μm or more and 10.0 μm or less.

9. The semiconductor device according to claim 2, wherein
a depth position of a second concentration peak that is closest, among the one or more concentration peaks in the group of auxiliary peaks, to the back surface of the semiconductor substrate in the depth direction of the semiconductor substrate is at 3.0 μm or more from the back surface of the semiconductor substrate.

10. The semiconductor device according to claim 2, wherein
a depth position of a concentration peak that is closest, among the one or more concentration peaks in the group of auxiliary peaks, to the front surface of the semiconductor substrate in the depth direction of the semiconductor substrate is at 10.0 μm or less from the back surface from the semiconductor substrate.

11. The semiconductor device according to claim 2, wherein
the first dopant is phosphorous.

12. The semiconductor device according to claim 2, wherein
the semiconductor substrate includes a second hydrogen peak in the front surface side of the semiconductor substrate relative to a concentration peak that is closest, among the one or more concentration peaks in the group of auxiliary peaks, to the front surface of the semiconductor substrate in the depth direction of the semiconductor substrate.

13. The semiconductor device according to claim 12, wherein
the second hydrogen peak is provided between a concentration peak that is closest, among the one or more concentration peaks in the group of auxiliary peaks, to the front surface of the semiconductor substrate, and the drift region in the depth direction of the semiconductor substrate.

14. The semiconductor device according to claim 1, wherein
an atomic density of the first hydrogen peak is 1.0E+17 cm⁻³ or more and 1.0E+19 cm⁻³ or less.

15. The semiconductor device according to claim 1, wherein
a depth position of the first hydrogen peak is at more than 0 μm and less than 10.0 μm from the back surface of the semiconductor substrate in the depth direction of the semiconductor substrate.

16. The semiconductor device according to claim 1, comprising
an edge termination structure portion provided in the front surface of the semiconductor substrate.

17. The semiconductor device according to claim 1, wherein
an integrated concentration obtained by integrating a doping concentration from an upper end of the drift region toward the back surface side of the semiconductor substrate in the depth direction of the semiconductor substrate reaches a critical integrated concentration in the buffer region.

18. The semiconductor device according to claim 17, wherein
the first hydrogen peak is provided in the back surface side of the semiconductor substrate relative to a depth position at which the integrated concentration reaches the critical integrated concentration in the depth direction of the semiconductor substrate.

19. The semiconductor device according to claim 1, comprising
a back-surface-side region that is provided in the back surface side of the semiconductor substrate relative to the drift region in the depth direction of the semiconductor substrate and that has a concentration peak of a doping concentration of a first conductivity type or a second conductivity type.

20. The semiconductor device according to claim 19, wherein
the first hydrogen peak is provided in the back surface side of the semiconductor substrate relative to the concentration peak in the back-surface-side region in the depth direction of the semiconductor substrate.

21. The semiconductor device according to claim 19, wherein
the first hydrogen peak is provided in a front surface side of the semiconductor substrate relative to the concentration peak in the back-surface-side region in the depth direction of the semiconductor substrate, the front surface side being a side of the front surface.

22. The semiconductor device according to claim 19, comprising
a diode portion, wherein
the diode portion has a cathode region of a first conductivity type as the back-surface-side region.

23. The semiconductor device according to claim 22, wherein
a doping concentration of a concentration peak in the cathode region is 1.0E+18 cm⁻³ or more and 1.0E+20 cm⁻³ or less.

24. The semiconductor device according to claim 22, wherein
a depth position of a concentration peak of a doping concentration in the cathode region is at more than 0 μm and less than 1.0 μm from the back surface of the semiconductor substrate in the depth direction of the semiconductor substrate.

25. The semiconductor device according to claim 19, comprising
a transistor portion, wherein
the transistor portion has a collector region of a second conductivity type as the back-surface-side region.

26. The semiconductor device according to claim 25, wherein
a doping concentration of a concentration peak in the collector region is 1.0E+15 cm⁻³ or more and 1.0E+18 cm⁻³ or less.

27. The semiconductor device according to claim 25, wherein
a depth position of a concentration peak of a doping concentration in the collector region is at more than 0 μm and less than 0.5 μm from the back surface of the semiconductor substrate in the depth direction of the semiconductor substrate.

28. The semiconductor device according to claim 1, wherein
the semiconductor device is an RC-IGBT having a transistor portion and a diode portion.

29. A manufacturing method for a semiconductor device comprising:
forming a drift region of a first conductivity type in a semiconductor substrate having a front surface and a back surface; and,
forming a buffer region of a first conductivity type in a back surface side of the semiconductor substrate relative to the drift region in a depth direction of the semiconductor substrate, the back surface side being a side of the back surface, wherein
the buffer region has a group of concentration peaks including one or more concentration peaks of a doping concentration,
the group of concentration peaks includes a first concentration peak that is provided closest, among the one or more concentration peaks, to the back surface of the semiconductor substrate in the depth direction of the semiconductor substrate
the semiconductor substrate includes a first hydrogen peak which is a peak of an atomic density of hydrogen, provided in a same depth position as a depth position of the first concentration peak or in the back surface side of the semiconductor substrate relative to a depth position of the first concentration peak in the depth direction of the semiconductor substrate.

30. The manufacturing method for a semiconductor device according to claim 29, comprising
forming a back-surface-side region that includes a concentration peak of a doping concentration of a first conductivity type or a second conductivity type in the back surface side of the semiconductor substrate relative to the drift region in the depth direction of the semiconductor substrate.

31. The manufacturing method for a semiconductor device according to claim 30, comprising,
after the forming the back-surface-side region, ion-implanting a first dopant predetermined other than hydrogen into the semiconductor substrate for forming a group of auxiliary peaks that includes one or more concentration peaks provided in a front surface side of the semiconductor substrate relative to the first concentration peak in the depth direction of the semiconductor substrate, the front surface side being a side of the front surface.

32. The manufacturing method for a semiconductor device according to claim 31, wherein
laser-annealing the semiconductor substrate is not included after the forming the back-surface-side region and before the ion-implanting the first dopant into the semiconductor substrate for forming the group of auxiliary peaks.

33. The manufacturing method for a semiconductor device according to claim 31, wherein
laser-annealing the semiconductor substrate is included after the forming the back-surface-side region and before the ion-implanting the first dopant into the semiconductor substrate for forming the group of auxiliary peaks.

34. The manufacturing method for a semiconductor device according to claim 31, comprising:
laser-annealing the semiconductor substrate after the ion-implanting the first dopant into the semiconductor substrate for forming the group of auxiliary peaks;
ion-implanting hydrogen into the semiconductor substrate for forming the first hydrogen peak; and
thermal-annealing the semiconductor substrate after ion-implanting the hydrogen.

35. The manufacturing method for a semiconductor device according to claim 31, comprising:
ion-implanting hydrogen into the semiconductor substrate for forming the first hydrogen peak, after the ion-implanting the first dopant into the semiconductor substrate for forming the group of auxiliary peaks; and
thermal-annealing the semiconductor substrate after the ion-implanting hydrogen, wherein
laser-annealing the semiconductor substrate is not included after the ion-implanting the first dopant into the semiconductor substrate and before the ion-implanting hydrogen into the semiconductor substrate.
